(19) United States
(12) Patent Application Publication
(10) Pub. No.: US 2026/0020393 A1
(43) Pub. Date: Jan. 15, 2026

(54) Light-Emitting Device and Method for Manufacturing the Same, Backlight Module and Display Apparatus

(71) Applicant: BOE TECHNOLOGY GROUP CO., LTD., Chaoyang District, Beijing (CN)

(72) Inventors: Qian Sun, Beijing (CN); Mingxing Wang, Beijing (CN); Huajie Yan, Beijing (CN); Wei Li, Beijing (CN); Zhiqiang Jiao, Beijing (CN)

(21) Appl. No.: 18/995,085

(22) PCT Filed: Mar. 27, 2023
(86) PCT No.: PCT/CN2023/084189

§ 371 Date: Jan. 15, 2025

(51) Int. Cl. H10H 20/855; G02F 1/13357; H10H 20/01; H10H 20/831

(52) U.S. Cl. CPC H10H 20/855; G02F 1/133603; H10H 20/032; H10H 20/0363; H10H 20/8312

(57) ABSTRACT

A light-emitting device includes a metal wire grid; a first semiconductor layer located on a side of the metal wire grid; a light-emitting layer located on a side of the first semiconductor layer away from the metal wire grid; a second semiconductor layer located on a side of the light-emitting layer away from the metal wire grid, a surface of the second semiconductor layer away from the first semiconductor layer being provided with a plurality of grooves; and a phase deflection layer covering the second semiconductor layer, and portions of the phase deflection layer being located in the plurality of grooves.

### CROSS-REFERENCE TO RELATED APPLICATION

This application is the United States national of International Patent Application No. PCT/CN2023/084189, filed Mar. 27, 2023, the disclosure of which is hereby incorporated by reference in its entirety.

### BACKGROUND OF THE INVENTION

### Field of the Invention

The present disclosure relates to the field of display technologies, and in particular, to a light-emitting device and a method for manufacturing the same, a backlight module and a display apparatus.

### Description of Related Art

Metal wire grid (wire grid polarizer (WGP)) is a wire grid polarizing device with good polarization performance, high transmittance and relatively flexible design freedom. Wire grid polarizers can also be used as polarization beam splitters.

Metal wire grids can be used in light-emitting devices so that the light-emitting devices emit polarized light.

### SUMMARY OF THE INVENTION

In an aspect, a light-emitting device is provided, including: a metal wire grid, a first semiconductor layer, a light-emitting layer, a second semiconductor layer and a phase deflection layer. The first semiconductor layer is located on a side of the metal wire grid. The light-emitting layer is located on a side of the first semiconductor layer away from the metal wire grid. The second semiconductor layer is located on a side of the light-emitting layer away from the metal wire grid. A surface of the second semiconductor layer away from the first semiconductor layer is provided with a plurality of grooves. The phase deflection layer covers the second semiconductor layer, and portions of the phase deflection layer are located in the plurality of grooves.

In some embodiments, the metal wire grid includes a first metal layer, a light-transmitting medium layer and a second metal layer. The first metal layer includes a plurality of first metal patterns, each first metal pattern extends in a first direction, and the plurality of first metal patterns are arranged at intervals in a second direction, the first direction and the second direction intersecting. The light-transmitting medium layer includes a plurality of light-transmitting medium patterns, each light-transmitting medium pattern extends in the first direction, and the plurality of light-transmitting medium patterns are arranged at intervals in the second direction. The light-transmitting medium pattern is located between two adjacent first metal patterns. A thickness of the light-transmitting medium pattern is greater than a thickness of the first metal pattern. The second metal layer includes a plurality of second metal patterns, each second metal pattern extends in the first direction, and the plurality of second metal patterns are arranged at intervals in the second direction. A second metal pattern is located on a surface of a light-transmitting medium pattern close to the first semiconductor layer.

In some embodiments, in a direction perpendicular to a plane where the metal wire grid is located and in the second direction, a shape of a section of the first metal pattern includes an upright trapezoid; and/or, in the direction perpendicular to the plane where the metal wire grid is located and in the second direction, a shape of a section of the second metal pattern includes an upright trapezoid.

In some embodiments, in a direction perpendicular to a plane where the metal wire grid is located and in the second direction, a shape of a section of the light-transmitting medium pattern includes an inverted trapezoid.

In some embodiments, a size of the first metal pattern in the second direction is in a range of 50 nm to 70 nm; and/or, a size of the second metal pattern in the second direction is in a range of 50 nm to 70 nm.

In some embodiments, a distance between any two adjacent first metal patterns in the second direction is substantially equal, and a distance between any two adjacent second metal patterns in the second direction is substantially equal; and/or, a size of each first metal pattern in the second direction is substantially equal, and a size of each second metal pattern in the second direction is substantially equal.

In some embodiments, the thickness of the first metal pattern is in a range of 50 nm to 60 nm; and/or a thickness of the second metal pattern is in a range of 50 nm to 60 nm.

In some embodiments, a thickness of the second metal pattern is substantially equal to the thickness of the first metal pattern.

In some embodiments, a refractive index of the light-transmitting medium pattern is in a range of 1.4 to 1.5.

In some embodiments, a ratio of the thickness of the light-transmitting medium pattern to the thickness of the first metal pattern is in a range of 1.17 to 1.60; and/or, a ratio between the thickness of the light-transmitting medium pattern and a thickness of the second metal pattern is in a range of 1.17 to 1.60.

In some embodiments, orthographic projections of the second semiconductor layer and the light-emitting layer on a plane where the metal wire grid is located are located within an orthographic projection of the first semiconductor layer on the plane where the metal wire grid is located. The light-emitting device further includes a first electrode and a second electrode. The first electrode is located on the side of the first semiconductor layer away from the metal wire grid, and is electrically connected to a portion of the first semiconductor layer extending beyond the light-emitting layer and the second semiconductor layer. The second electrode is located on a side of the phase deflection layer away from the metal wire grid, and is electrically connected to the second semiconductor layer through the phase deflection layer. The second metal layer is located on a side of the light-transmitting medium layer close to the first semiconductor layer; or, the light-emitting device further includes a connection layer located between the metal wire grid and the first semiconductor layer, and the second metal layer is located on a side of the light-transmitting medium layer close to the connection layer.

In some embodiments, orthographic projections of the second semiconductor layer, the light-emitting layer and the first semiconductor layer on a plane where the metal wire grid is located substantially coincide with each other. The light-emitting device further includes a first electrode and a second electrode. The first electrode is located on a side of the first semiconductor layer close to the metal wire grid, and is electrically connected to the first semiconductor layer penetrating through the metal wire grid. The second electrode is located on a side of the phase deflection layer away from the metal wire grid, and is electrically connected to the second semiconductor layer through the phase deflection layer. The second metal layer is located on a side of the light-transmitting medium layer away from the first semiconductor layer.

In some embodiments, the plurality of grooves are arranged in a plurality of rows and a plurality of columns; each row of grooves is arranged in a third direction, and each column of grooves is arranged in a fourth direction; a size of a groove in the fourth direction is greater than a size of the groove in the third direction, the third direction and the fourth direction intersecting and being parallel to a plane where the metal wire grid is located.

In some embodiments, the phase deflection layer includes a plurality of first sub-portions and a second sub-portion connected to the plurality of first sub-portions; a first sub-portion is located in a groove; the second sub-portion is located outside the grooves and located on a side of the second semiconductor layer away from the metal wire grid; a distance between a surface of the first sub-portion away from the light-emitting layer and the light-emitting layer is less than a distance between a surface of the second sub-portion away from the light-emitting layer and the light-emitting layer.

In some embodiments, a shape of an orthographic projection of the first sub-portion on the light-emitting layer includes a rectangle, an ellipse, or a strip shape.

In another aspect, a method for manufacturing a light-emitting device is provided. The method includes: providing an epitaxial structure, the epitaxial structure including a first semiconductor layer, a light-emitting layer, and a second semiconductor layer that are stacked in sequence; forming a plurality of grooves in a surface of the second semiconductor layer; forming a phase deflection layer on a side of the second semiconductor layer away from the first semiconductor layer, portions of the phase deflection layer being located in the plurality of grooves; and forming a metal wire grid on a side of the epitaxial structure away from the phase deflection layer.

In some embodiments, forming the metal wire grid on the side of the epitaxial structure away from the phase deflection layer includes: providing a base, the base including a first surface; forming a first metal layer on the first surface, wherein the first metal layer includes a plurality of first metal patterns, each first metal pattern extends in a first direction, and the plurality of first metal patterns are arranged at intervals in a second direction, the first direction and the second direction intersecting; forming a light-transmitting medium layer on the first surface, wherein the light-transmitting medium layer includes a plurality of light-transmitting medium patterns, each light-transmitting medium pattern extends in the first direction, and the plurality of light-transmitting medium patterns are arranged at intervals in the second direction; the light-transmitting medium pattern is located between any two adjacent first metal patterns; a thickness of the light-transmitting medium pattern is greater than a thickness of the first metal pattern; forming a first sacrificial pattern on each first metal pattern, wherein a sum of thicknesses of the first metal pattern and the first sacrificial pattern located on the first metal pattern is greater than the thickness of the light-transmitting medium pattern; depositing a second metal film on the plurality of light-transmitting medium patterns and a plurality of first sacrificial patterns, wherein in the second metal film, a portion of the second metal film located on each light-transmitting medium pattern and a portion of the second metal film located on each first sacrificial pattern are disconnected; removing each first sacrificial pattern and the portion of the second metal film located on each first sacrificial pattern so that the portion of the second metal film located on each light-transmitting medium pattern is remained to obtain a plurality of second metal patterns, wherein the plurality of second metal patterns constitute a second metal layer; the first metal layer, the light-transmitting medium layer and the second metal layer constitute the metal wire grid; and bonding the second metal layer of the metal wire grid to a surface of the epitaxial structure of the light-emitting device away from the phase deflection layer. Alternatively, forming the metal wire grid on the side of the epitaxial structure away from the phase deflection layer includes: forming a light-transmitting medium film on the first semiconductor layer; patterning the light-transmitting medium film using a nanoimprint process to form an imprinting residual adhesive and a plurality of protrusions located on the imprinting residual adhesive; and depositing a metal film on the plurality of protrusions and on a portion of the imprinting residual adhesive located between two adjacent protrusions, wherein a portion of the metal film located on the portion of the imprinting residual adhesive between two adjacent protrusions constitutes a first metal pattern, and a portion of the metal film located on a protrusion constitutes a second metal pattern; a first metal pattern and a second metal pattern that are adjacent are disconnected; a plurality of first metal patterns, a plurality of second metal patterns and the plurality of protrusions constitute the metal wire grid.

In some embodiments, forming the first metal layer on the first surface includes: forming a plurality of second sacrificial patterns on the first surface, wherein each second sacrificial pattern extends in the first direction, and the plurality of second sacrificial patterns are arranged at intervals in the second direction; depositing a first metal sub-film on the plurality of second sacrificial patterns and on a portion of the first surface located between any two adjacent second sacrificial patterns, wherein a portion of the first metal sub-film located on each second sacrificial pattern and a portion of the first metal sub-film located on the first surface are disconnected; and removing each second sacrificial pattern and the portion of the first metal sub-film located on each second sacrificial pattern so that the portion of the first metal sub-film located on the first surface is remained to obtain the plurality of first metal patterns, wherein the plurality of first metal patterns constitute the first metal layer.

In some embodiments, orthographic projections of the second semiconductor layer and the light-emitting layer on a plane where the metal wire grid is located are located within an orthographic projection of the first semiconductor layer on the plane where the metal wire grid is located. Before forming the metal wire grid on the side of the epitaxial structure away from the phase deflection layer, the method further includes: forming a first electrode and a second electrode, wherein the first electrode is located on a side of the first semiconductor layer away from the metal wire grid, and is electrically connected to a portion of the first semiconductor layer extending beyond the light-emitting layer and the second semiconductor layer; the second electrode is located on a side of the phase deflection layer away from the metal wire grid, and is electrically connected to the second semiconductor layer through the phase deflection layer.

In some embodiments, orthographic projections of the second semiconductor layer, the light-emitting layer and the first semiconductor layer on a plane where the metal wire grid is located substantially coincide with each other. Before forming the metal wire grid on the side of the epitaxial structure away from the phase deflection layer, the method further includes: providing a backplane, the backplane including a second base and a plurality of pads located on the second base; bonding the plurality of pads to the phase deflection layer; and removing the second base so that the plurality of pads are remained, wherein the plurality of pads constitute a second electrode, and the second electrode is electrically connected to the second semiconductor layer through the phase deflection layer. After forming the metal wire grid on the side of the epitaxial structure away from the phase deflection layer, the method further includes: forming a first electrode, wherein the first electrode is located on a side of the first semiconductor layer close to the metal wire grid, and is electrically connected to the first semiconductor layer penetrating through the metal wire grid.

In yet another aspect, a backlight module is provided. The backlight module includes the light-emitting device as described in any of the above embodiments.

In yet another aspect, a display apparatus is provided. The display apparatus includes: the backlight module as described in the above embodiment, or the light-emitting device as described in any of the above embodiments.

### BRIEF DESCRIPTION OF THE DRAWINGS

In order to describe technical solutions in the present disclosure more clearly, the accompanying drawings to be used in some embodiments of the present disclosure will be introduced briefly. However, the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on an actual size of a product and an actual process of a method involved in the embodiments of the present disclosure.

FIG. 1 is a schematic diagram of a display apparatus, in accordance with some embodiments of the present disclosure;

FIG. 2 is a structural diagram of another display apparatus, in accordance with some embodiments of the present disclosure;

FIG. 3 is a structural diagram of yet another display apparatus, in accordance with some embodiments of the present disclosure;

FIG. 4 is a structural diagram of yet another display apparatus, in accordance with some embodiments of the present disclosure;

FIG. 5 is a structural diagram of a display panel, in accordance with some embodiments of the present disclosure;

FIG. 6A is a structural diagram of a substrate and light-emitting devices, in accordance with some embodiments of the present disclosure;

FIG. 6B is a structural diagram of a substrate and light-emitting devices, in accordance with some other embodiments of the present disclosure;

FIG. 6C is a structural diagram of a substrate and light-emitting devices, in accordance with yet some other embodiments of the present disclosure;

FIG. 6D is a structural diagram of a driving circuit and light-emitting devices, in accordance with some embodiments of the present disclosure;

FIG. 7 is a structural diagram of a display apparatus in the related art;

FIG. 8 is a structural diagram of an improved display apparatus the related art;

FIG. 9 is a structural diagram of a light-emitting device, in accordance with some embodiments of the present disclosure;

FIG. 10 is a structural diagram of another light-emitting device, in accordance with some embodiments of the present disclosure;

FIG. 11 is a diagram showing a relationship between a size of a first metal pattern of a metal wire grid in a second direction and a light transmittance and absorptivity of the metal wire grid, in accordance with some embodiments of the present disclosure;

FIG. 12 is a diagram showing a relationship between a thickness of a first metal pattern of a metal wire grid and a light transmittance, absorptivity, and reflectivity of the metal wire grid, in accordance with some embodiments of the present disclosure;

FIG. 13 is a diagram showing a relationship between a refractive index of a light-transmitting medium pattern in a metal wire grid and a light transmittance and absorptivity of the metal wire grid, in accordance with some embodiments of the present disclosure;

FIG. 14 is a diagram showing a relationship between a thickness of a light-transmitting medium pattern in a metal wire grid and a light transmittance, absorptivity, and reflectivity of the metal wire grid, in accordance with some embodiments of the present disclosure;

FIG. 15 is a diagram showing a relationship between a thickness of a light-transmitting medium pattern in a metal wire grid and a degree of polarization of the metal wire grid, in accordance with some embodiments of the present disclosure;

FIG. 16 is a structural diagram of a phase deflection layer, in accordance with some embodiments of the present disclosure;

FIG. 17 is a structural diagram of another phase deflection layer, in accordance with some embodiments of the present disclosure;

FIG. 18 is a structural diagram of yet another phase deflection layer, in accordance with some embodiments of the present disclosure;

FIG. 19 is a structural diagram of yet another light-emitting device, in accordance with some embodiments of the present disclosure;

FIG. 20 is a diagram showing a process of manufacturing a light-emitting device, in accordance with some embodiments of the present disclosure;

FIGS. 21 to 24 are diagrams showing structures of a light-emitting device in different manufacturing steps, in accordance with some embodiments of the present disclosure;

FIG. 25 is a diagram showing a process of manufacturing a light-emitting device, in accordance with some other embodiments of the present disclosure;

FIGS. 26 to 35 are diagrams showing structures of a light-emitting device in different manufacturing steps, in accordance with some other embodiments of the present disclosure;

FIG. 36 is a diagram showing a process of manufacturing a light-emitting device, in accordance with yet some other embodiments of the present disclosure;

FIG. 37 is a diagram showing a process of manufacturing a light-emitting device, in accordance with yet some other embodiments of the present disclosure;

FIGS. 38 to 40 are diagrams showing structures of a light-emitting device in different manufacturing steps, in accordance with yet some other embodiments of the present disclosure;

FIG. 41 is a diagram showing a process of manufacturing a light-emitting device, in accordance with yet some other embodiments of the present disclosure;

FIGS. 42 to 44 are diagrams showing structures of a light-emitting device in different manufacturing steps, in accordance with yet some other embodiments of the present disclosure;

FIGS. 45 to 48 are diagrams showing structures of a light-emitting device in different manufacturing steps, in accordance with yet some other embodiments of the present disclosure;

FIG. 49 is a diagram showing a process of manufacturing a light-emitting device, in accordance with yet some other embodiments of the present disclosure; and

FIGS. 50 to 53 are diagrams showing structures of a light-emitting device in different manufacturing steps, in accordance with yet some other embodiments of the present disclosure.

### DESCRIPTION OF THE INVENTION

The technical solutions in some embodiments of the present disclosure will be described clearly and completely with reference to the accompanying drawings. However, the described embodiments are merely some but not all embodiments of the present disclosure. All other embodiments obtained by a person of ordinary skill in the art based on embodiments of the present disclosure shall be included in the protection scope of the present disclosure.

Unless the context requires otherwise, throughout the specification and the claims, the term “comprise” and other forms thereof such as the third-person singular form “comprises” and the present participle form “comprising” are construed as an open and inclusive meaning, i.e., “including, but not limited to.” In the description of the specification, the terms such as “one embodiment,” “some embodiments,” “exemplary embodiments,” “example,” “specific example,” or “some examples” are intended to indicate that specific features, structures, materials, or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics may be included in any one or more embodiments or examples in any suitable manner.

The terms “first” and “second” are used for descriptive purposes only, and are not to be construed as indicating or implying a relative importance or implicitly indicating a number of indicated technical features. Thus, features defined with “first” and “second” may explicitly or implicitly include one or more of the features. In the description of the embodiments of the present disclosure, the term “multiple”, “a plurality of” or “the plurality of” means two or more unless otherwise specified.

The phrase “A and/or B” includes following three combinations: only A, only B, and a combination of A and B.

The phrase “applicable to” or “configured to” used herein means an open and inclusive expression, which does not exclude devices that are applicable to or configured to perform additional tasks or steps.

The term such as “about,” “substantially,” and “approximately” as used herein includes a stated value and an average value within an acceptable range of deviation of a particular value. The acceptable range of deviation is determined by a person of ordinary skill in the art, considering measurement in question and errors associated with measurement of a particular quantity (i.e., limitations of a measurement system).

The term such as “perpendicular” or “equal” as used herein includes a stated condition and a condition similar to the stated condition. A range of the similar condition is within an acceptable deviation range, and the acceptable deviation range is determined by a person of ordinary skill in the art, considering measurement in question and errors associated with measurement of a particular quantity (i.e., the limitations of a measurement system). For example, the term “perpendicular” includes absolute perpendicularity and approximate perpendicularity, and an acceptable range of deviation of the approximate perpendicularity may also be, for example, a deviation within 5°. The term “equal” includes absolute equality and approximate equality, and an acceptable range of deviation of the approximate equality may be, for example, that a difference between two equals is less than or equal to 5% of either of the two equals.

It will be understood that, when a layer or element is referred to as being on another layer or substrate, it may be that the layer or element is directly on the another layer or substrate, or it may be that intervening layer(s) exist between the layer or element and the another layer or substrate.

Exemplary embodiments are described herein with reference to sectional views and/or plan views that are schematic illustrations of idealized embodiments. In the accompanying drawings, thicknesses of layers and areas of regions are enlarged for clarity. Variations in shape with respect to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown to have a rectangular shape generally has a feature of being curved. Therefore, the regions shown in the accompanying drawings are schematic in nature, and their shapes are not intended to show actual shapes of the regions in a device, and are not intended to limit the scope of the exemplary embodiments.

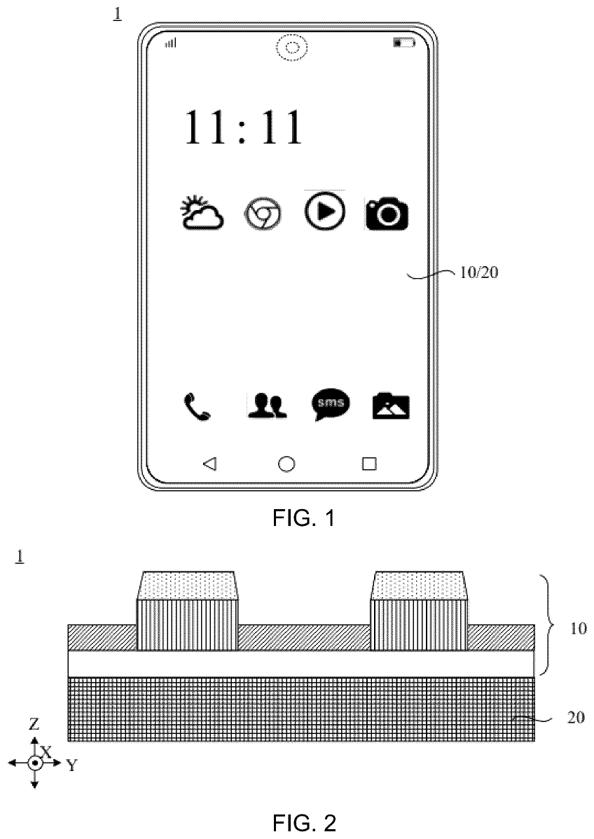

As shown in FIG. 1, some embodiments of the present disclosure provide a display apparatus 1. The display apparatus 1 may be any display apparatus that can display an image whether in motion (e.g., a video) or stationary (e.g., a still image), and whether textual or graphical. More specifically, it is expected that the display apparatus in the embodiments may be implemented in or associated with a plurality of electronic devices. The plurality of electronic devices may include (but are not limit to), for example, mobile telephones, wireless devices, personal data assistants (PDAs), hand-held or portable computers, GPS receivers/navigators, cameras, MP4 video players, video cameras, game consoles, watches, clocks, calculators, TV monitors, flat panel displays, computer monitors, car displays (such as odometer displays), navigators, cockpit controllers and/or displays, camera view displays (such as rear view camera displays in vehicles), electronic photos, electronic billboards or indicators, projectors, building structures, packagings and aesthetic structures (such as displays for an image of a piece of jewelry), etc.

For example, the display apparatus 1 includes: a frame, a display driver integrated circuit (IC), and other electronic components.

In some embodiments, as shown in FIG. 2, the display apparatus 1 further includes a metal wire grid 10 and a display panel 20.

For example, among rays of light incident on the metal wire grid 10, rays of light perpendicular to a transmission axis direction of the metal wire grid 10 may pass through the metal wire grid 10, and rays of light parallel to the transmission axis direction of the metal wire grid 10 may be reflected by the metal wire grid 10.

In some examples, as shown in FIG. 2, the display panel 20 may include a light-emitting substrate. The light-emitting substrate may be directly used as the display panel for displaying images. The display apparatus 1 is an active light-emitting display apparatus. Since the light-emitting substrate itself can emit light, there is no need to configure an additional backlight module.

For example, the light-emitting substrate 30 may include light-emitting devices. For example, the light-emitting devices may include light-emitting diodes (LEDs). In this case, the metal wire grid 10 is located on a light-exit side of the display panel 20.

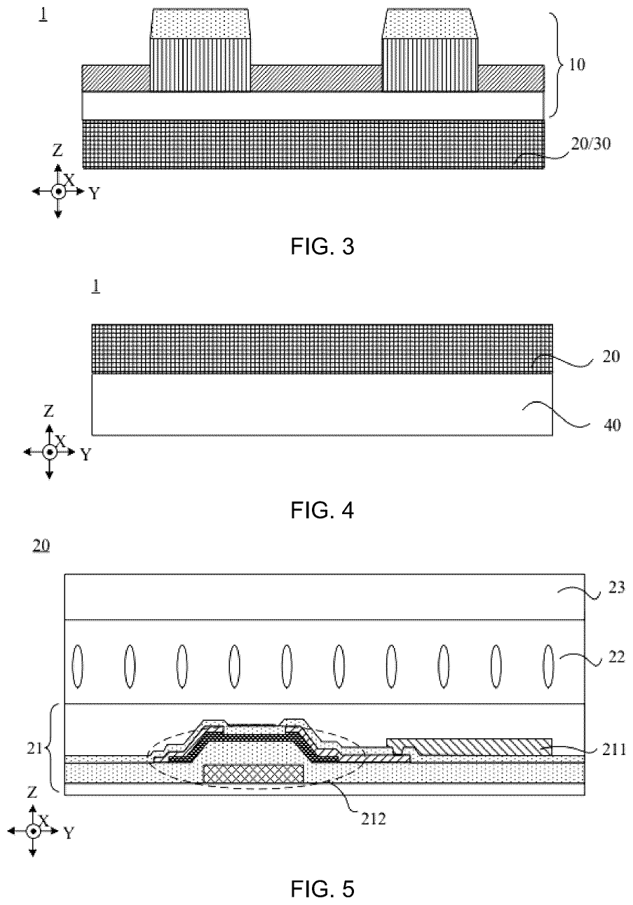

In some other examples, as shown in FIG. 3, the display panel 20 may be an organic light-emitting diode (OLED) display panel. In this case, the metal wire grid 10 is located on the light-exit side of the display panel 20.

For example, the display panel 20 includes: a backplane and a plurality of light-emitting devices located on a side of the backplane.

For example, the backplane may include a plurality of pixel circuits, and the plurality of pixel circuits and the plurality of light-emitting devices may be electrically connected in a one-to-one correspondence. A light-emitting device may emit light under control of a control signal transmitted by a pixel circuit.

For example, the light-emitting devices may be OLED light-emitting devices.

For example, light emitted by the display panel 20 may include a first type of light and a second type of light. A polarization direction of the first type of light is perpendicular to the transmission axis direction of the metal wire grid 10 (here, considering an example in which the transmission axis of the metal wire grid 10 is a first direction X, the first type of light may be light along a direction of a transverse magnetic field, and the first type of light may be referred to as TM light). A polarization direction of the second type of light is parallel to the transmission axis direction of the metal wire grid 10 (here, considering an example in which the transmission axis of the metal wire grid 10 is the first direction X, the second type of light may be light along a direction of a transverse electric field, and the second type of light may be referred to as TE light). Therefore, the TM light may pass through the metal wire grid 10, and the TE light is reflected by the metal wire grid 10. Thus, the metal wire grid 10 may be used to filter the light emitted by the display panel 20 such that polarization directions of the light emitted by the display apparatus 1 are substantially the same. As a result, it may be possible to improve the display effect of the display apparatus 1, and to avoid blooming phenomenon in images displayed by the display apparatus 1 (images displayed especially when the display apparatus in a dark display state or when the brightness is low) due to different polarization directions of the light emitted by the display apparatus 1.

In yet some other examples, the display panel 20 may be a liquid crystal display (LCD) display panel.

For example, as shown in FIG. 4, the display apparatus 1 further includes a backlight module 40.

For example, the backlight module 40 is used to provide backlight for the display panel 20. The display panel 20 is disposed on a light-exit side of the backlight module 40. The light-exit side of the backlight module 40 refers to a side from which the backlight module 40 emits light.

For example, a driving mode of the display panel 20 may be a passive matrix (PM) driving mode or an active matrix (AM) driving mode. In the case where the driving mode of the display panel 20 is the AM driving mode, the display panel 20 may be, for example, a thin film transistor liquid crystal display (TFT-LCD) display panel.

For example, as shown in FIG. 5, the display panel 20 may include an array substrate 21, a liquid crystal layer 22, and a color filter substrate 23 that are stacked in sequence.

For example, the array substrate 21 may include a plurality of pixel electrodes 211 and a plurality of pixel driving circuits 212. The plurality of pixel electrodes 211 and the plurality of pixel driving circuits 212 are electrically connected in a one-to-one correspondence. A pixel driving circuit 212 provides a pixel voltage to a corresponding pixel electrode 211.

For example, the display panel 20 further includes a common electrode.

The location of the common electrode is related to the display type of the display panel 20. In the embodiments of the present disclosure, the display type of the display panel 20 may be an Advanced Super Dimension Switch (ADS) display type, an In-Plane Switching (IPS) display type, Vertical Alignment (VA) display type, Fringe Field Switching (FFS) display type, Twisted Nematic (TN) display type, etc. Therefore, in the embodiments of the present disclosure, the location of the common electrode varies.

For example, in the case where the display panel 20 is of the IPS display type, the common electrode may be arranged in the array substrate 21, and the common electrode and the pixel electrodes 211 are arranged in the same layer. In this case, the common electrode and the pixel electrodes 211 may be formed simultaneously through one patterning process, thereby simplifying the manufacturing process of the display panel 20.

For another example, when the display panel 20 is of the FFS display type or the ADS display type, the common electrode may be arranged in the array substrate 21, and the common electrode and the pixel electrodes 211 are located in different layers. Therefore, it may be possible to avoid mutual interference between the pixel voltage signal on the pixel electrode 211 and the common voltage on the common electrode, and improve the signal accuracy of the pixel voltage signal and the common voltage.

For another example, when the display panel 20 is of the TN display type or the VA display type, the common electrode may be arranged in the color filter substrate 23.

For example, the liquid crystal layer 22 includes a plurality of liquid crystal molecules. For example, the display panel 20 is of the TN display type, an electric field may be created between the pixel electrode 211 and the common electrode, and liquid crystal molecules located between the pixel electrode 210 and the common electrode may be deflected due to the electric field.

For example, the color filter substrate 23 includes a plurality of color filters. For example, when the backlight provided by the backlight module 40 is white light, the color filters may include red filters, green filters, and blue filters. For example, the red filters may only transmit red light of incident light, the green filters may only transmit green light of the incident light, and the blue filters may only transmit blue light of the incident light. For another example, when the backlight provided by the backlight module 40 is blue light, the color filters may include red filters and green filters.

Of course, the color filter substrate 23 further includes a black matrix for preventing light mixing.

It will be understood that the backlight provided by the backlight module 40 may pass through the array substrate 21 and be incident on liquid crystal molecules in the liquid crystal layer 22. Due to the electric field created between the pixel electrode 211 and the common electrode, the liquid crystal molecules are deflected to a certain extent, thus changing the polarization direction of light passing through the liquid crystal molecules. The light passes through the filters of different colors in the color filter substrate 23 and then emits. The emitted light includes light of various colors, such as red light, green light, blue light, etc. The light of various colors cooperate with each other to enable the display apparatus 1 to display images.

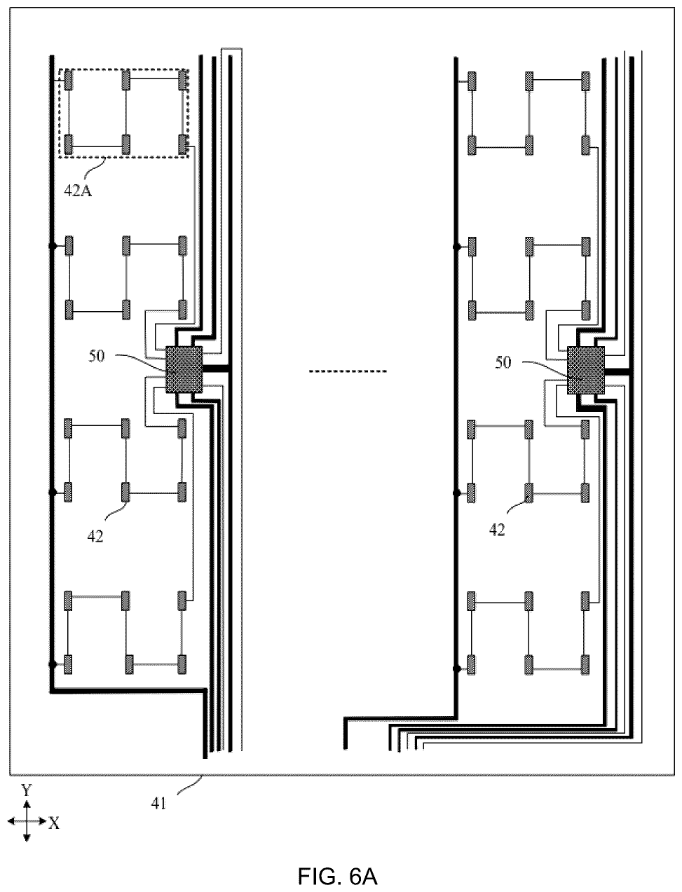

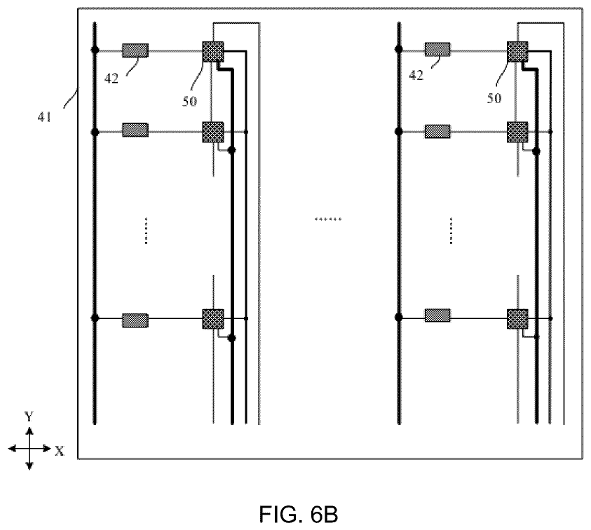

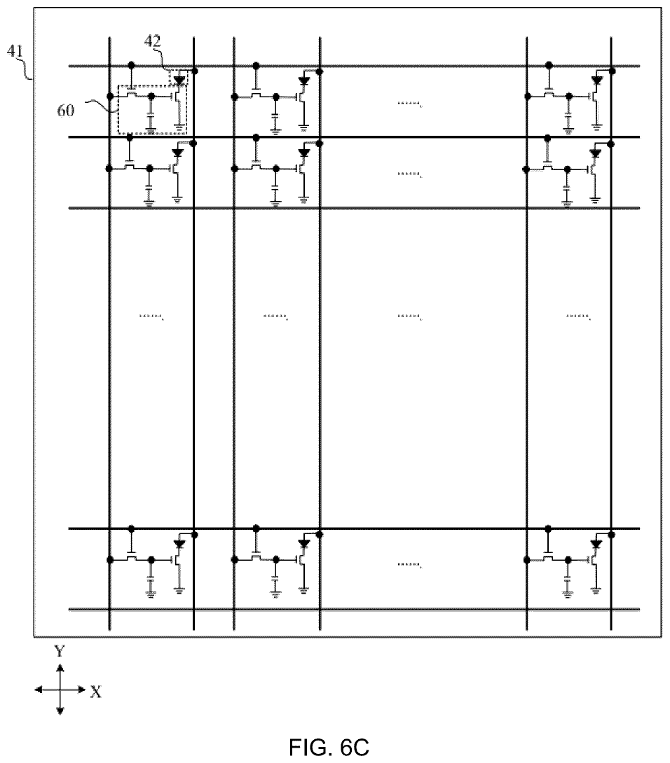

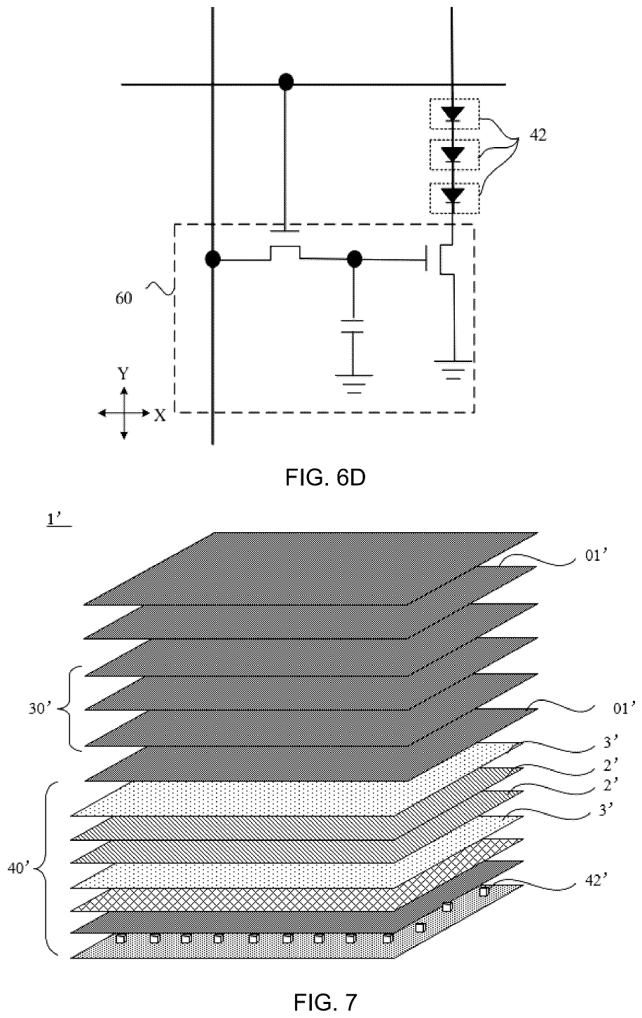

In some embodiments, as shown in FIGS. 6A to 6C, the backlight module 40 includes a substrate 41 and a plurality of light-emitting devices 42.

For example, the light-emitting devices 42 may be LED light-emitting devices.

For example, the plurality of light-emitting devices 42 emit light under control of the substrate 41.

It will be understood that the method of the substrate 41 controlling working states of the plurality of light-emitting devices 42 varies, which may be set according to the actual situations and will not be limited in the embodiments of the present disclosure.

In some examples, as shown in FIGS. 6A and 6B, the substrate 41 includes a plurality of chips 50, and the plurality of chips 50 may be arranged in a plurality of rows and a plurality of columns. A chip 50 is electrically connected to at least one light-emitting device 42.

For example, as shown in FIG. 6B, one chip 50 is electrically connected to one light-emitting device 42; and one chip 50 controls the working state of one light-emitting device 42 electrically connected thereto.

For another example, as shown in FIG. 6A, one chip 50 is electrically connected to multiple light-emitting devices 42; and one chip 50 controls the working states of the multiple light-emitting devices 42 electrically connected thereto.

It will be understood that each chip 50 works independently, so that different working states of different light-emitting devices 42 electrically connected to different chips may be controlled.

For example, in the case where one chip 50 is electrically connected to multiple light-emitting devices 42, the method of electrical connecting the multiple light-emitting devices 42 to the chip 50 varies, which may be set according to actual needs and will not be limited in the embodiments of the present disclosure.

For example, the multiple light-emitting devices 42 are individually and directly electrically connected to the same chip 50.

For another example, as shown in FIG. 6A, at least two light-emitting devices 42 are connected in series to form a light-emitting device group 42A, and at least one light-emitting device group 42A is electrically connected to one chip 50.

In this way, the chips 50 in the substrate 41 may control the plurality of light-emitting devices 42 to emit light, which may facilitate the control of the light-emitting devices 42 by the substrate 41 and ensuring that the backlight module 40 can provide backlight for the display panel 20.

In some other examples, as shown in FIG. 6C, the substrate 41 may include a plurality of driving circuits 60. The plurality of driving circuits 60 may be arranged in a plurality of rows and a plurality of columns.

In some examples, as shown in FIGS. 6C and 6D, a driving circuit 60 is electrically connected to at least one light-emitting device 42. The driving circuit 60 transmits a control signal to the light-emitting device(s) 42 electrically connected thereto, thereby controlling the light-emitting device(s) 42 to emit light.

For example, as shown in FIG. 6C, one driving circuit 60 is electrically connected to one light-emitting device 42.

For example, as shown in FIG. 6D, one driving circuit 60 is electrically connected to multiple light-emitting devices 42, and the multiple light-emitting devices 42 may be connected in series.

The above arrangement provides an implementation of the substrate 41 controlling the working states of the light-emitting devices 42. Therefore, the plurality of driving circuits 60 in the substrate 41 may be used to control the plurality of light-emitting devices 42 to emit light. Thus, the backlight module 40 may provide backlight for the display panel. As a result, the structure of the substrate 41 is simple, which facilitates the manufacturing of the substrate 41 and the backlight module 40.

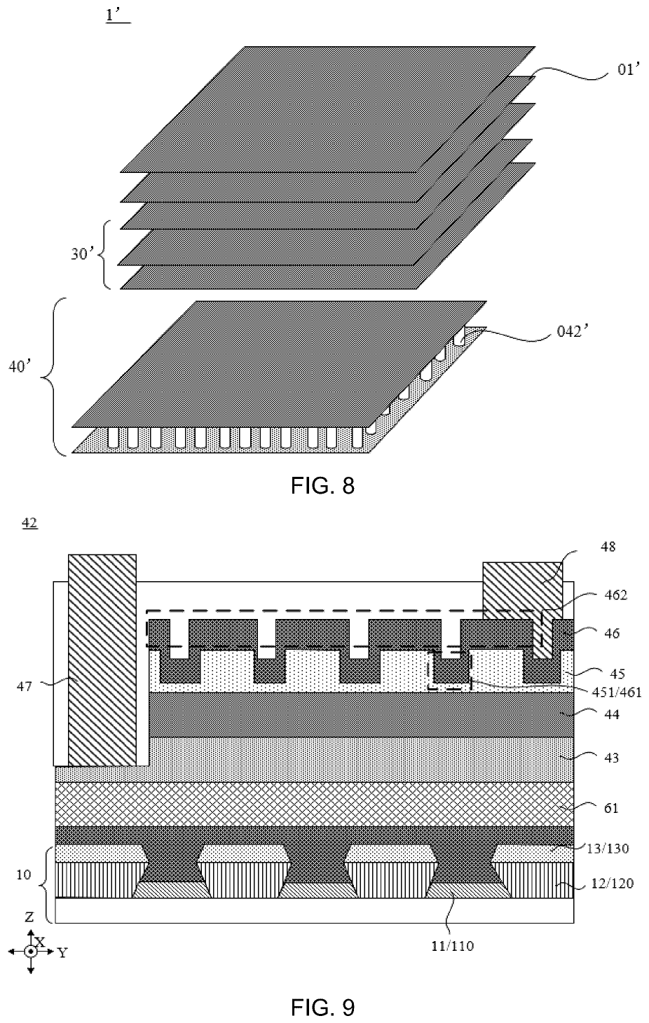

In an implementation, as shown in FIG. 7, in some display products (or display apparatuses) 1′, polarizers 01′ and the like are generally used to control light. Considering an example in which the display apparatus 1′ includes a backlight module 40′ and a display panel 30′, in order to cooperate with the polarizer, the display apparatus and the backlight module 40′ need to be provided therein with many film layers (such as two polarizers 01′, two prism sheets 2′, two diffusion sheets 3′, etc.) to cooperate with the polarizer, leading to the large overall thickness and complex structure of the display apparatus. Therefore, with reference to FIGS. 7 and 8, the inventors improved the display apparatus and replaced the light-emitting devices 42′ and prism sheets in the backlight module 40′ in FIG. 7 with single-polarization light-emitting devices 042′ in FIG. 8. As a result, the use of the polarizers and prism sheets may be reduced, and the thickness of the display apparatus 1′ is effectively reduced. The single-polarization light-emitting device generally includes a wire grid structure. However, the light transmittance of the wire grid structure is low. For example, among light emitted by the light-emitting layer in the single-polarization light-emitting device 042′, only part of the light (whose polarization direction is perpendicular to the transmission axis direction of the wire grid structure) may pass through the metal wire grid, and another part of the light (whose polarization direction is parallel to the transmission axis direction of the wire grid structure) is reflected by the wire grid structure, leading to a large light consumption of single-polarization light-emitting device and a low light extraction efficiency. As a result, the light extraction efficiency of the backlight module is low, and the power consumption of the display apparatus is high.

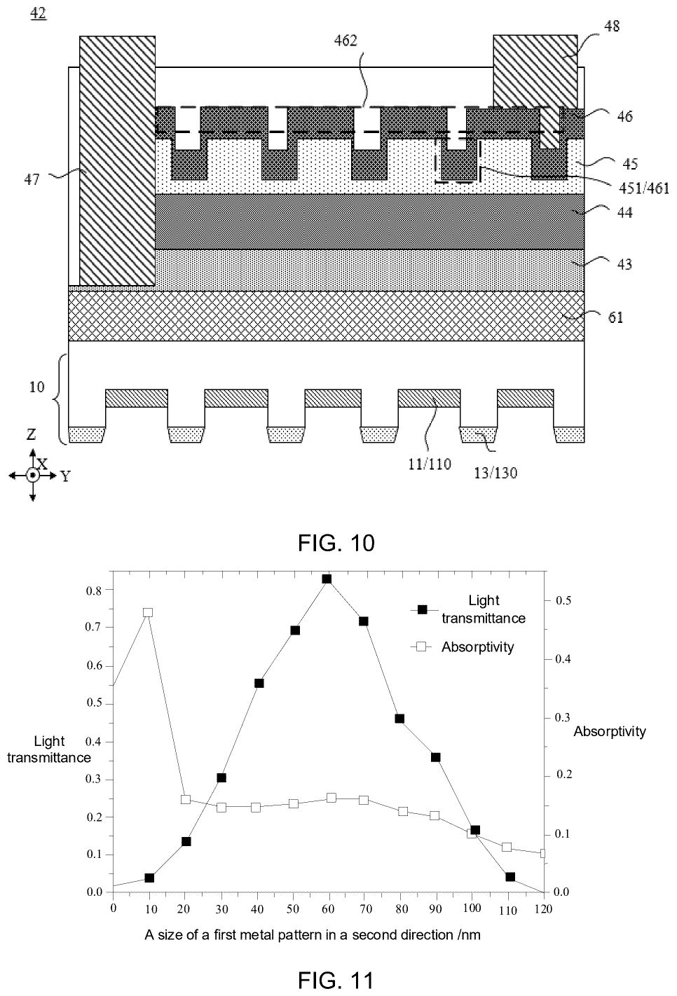

In light of this, some embodiments of the present disclosure provide a light-emitting device. As shown in FIGS. 9 and 10, the light-emitting device 42 includes: a metal wire grid 10, a first semiconductor layer 43, a light-emitting layer 44, a second semiconductor layer 45, and a phase deflection layer 46.

For example, the metal wire grid 10 may have a single-layer wire grid structure or a double-layer wire grid structure.

For example, the TM light may pass through the metal wire grid 10, and the TE light may be reflected on the metal wire grid 10.

For example, a distance between metal patterns (e.g. first metal patterns or second metal patterns mentioned below) in the metal wire grid 10 has a sub-wavelength order, so that the metal wire grid 10 has certain polarization properties within a visible light wavelength range.

For example, the first semiconductor layer 43 is located on a side of the metal wire grid 10.

For example, the first semiconductor layer 43 may be made of n-type gallium nitride (n-GaN).

For example, the light-emitting layer 44 is located on a side of the first semiconductor layer 43 away from the metal wire grid 10.

For example, the light-emitting layer 44 may be made of multiple quantum wells (MQW).

For example, the second semiconductor layer 45 is located on a side of the light-emitting layer 44 away from the metal wire grid 10.

For example, the second semiconductor layer 45 may be made of p-type gallium nitride (p-GaN).

For example, the first semiconductor layer 43, the light-emitting layer 44 and the second semiconductor layer 45 that are stacked constitute an epitaxial structure.

For example, when different voltages are applied to the first semiconductor layer 43 and the second semiconductor layer 45, a voltage difference is created between the first semiconductor layer 43 and the second semiconductor layer 45, and the light-emitting layer 44 emits light (e.g. nature light) due to the voltage difference.

For example, a surface of the second semiconductor layer 45 away from the first semiconductor layer 43 is provided with a plurality of grooves 451. The plurality of grooves 451 are arranged at intervals. The plurality of grooves 451 may have the same shape.

For example, the phase deflection layer 46 covers the second semiconductor layer 45, and portions of the phase deflection layer 46 are located in the plurality of grooves 451.

For example, with reference to the light-emitting devices 42 shown in FIG. 9, an outer contour of a surface of the phase deflection layer 46 away from the light-emitting layer 44 is similar to an outer contour of a surface of the second semiconductor layer 45 away from the light-emitting layer 44. The whole phase deflection layer 46 has periodic ups and downs along with the grooves of the surface of the second semiconductor layer 45. A surface of the phase deflection layer 46 close to the light-emitting layer 44 is uneven and is a non-flat surface.

For example, as shown in FIG. 9, the groove 451 is recessed in a direction in which the second semiconductor layer 45 points toward the light-emitting layer 44.

It will be understood that the wavelength range of the light emitted by the light-emitting device 42 varies, and depths of the grooves 451 vary correspondingly. Of course, the depths of the grooves 451 are smaller than a thickness of the second semiconductor layer 45. For example, in the case where the light-emitting device 42 emits green light, the depths of the grooves 451 may be set to 150 nm.

For example, after the light emitted by the light-emitting layer 44 reaches the phase deflection layer 46, the deflection direction of the light will change.

For example, the light emitted by the light-emitting layer 44 may include TM light and TE light. The polarization direction of the TM light is perpendicular to the transmission axis direction of the metal wire grid 10, so that the TM light may pass through the metal wire grid 10. The polarization direction of the TE light is parallel to the transmission axis direction of the metal wire grid 10. The TE light, after being reflected by the metal wire grid 10, is incident on the phase deflection layer 46. The phase deflection layer 46 may change the polarization direction of the TE light, so that the TE light is converted to TM light. The TM light will be incident on the metal wire grid 10 again and exit from the metal wire grid 10. Therefore, an amount of light emitted by the light-emitting layer 44 exiting from the metal wire grid 10 may be increased, which may increase the light extraction efficiency of the light-emitting device 42.

For example, the light-emitting device 42 is a single-polarization light-emitting device; and the light emitted by the single-polarization light-emitting device is of a single polarization state, for example, is TM light.

In the light-emitting device 42 provided in some embodiments of the present disclosure, the metal wire grid 10, the first semiconductor layer 43, the light-emitting layer 44, the second semiconductor layer 45 and the phase deflection layer 46 are stacked; the surface of the second semiconductor layer 45 away from the first semiconductor layer 43 is provided with a plurality of grooves 451; and portions of the phase deflection layer 46 are located in the grooves 451. Therefore, among the light emitted by the light-emitting layer 44, the TM light passes through the metal wire grid 10 and exits, and the TE light is reflected on the metal wire grid 10 and then incident on the portions of the phase deflection layer 46 located in the grooves 451. The TE light undergoes phase delay and its polarization direction changes, and at least part of the TE light is changed into TM light and then exits from the metal wire grid 10. Thus, the light transmittance of the metal wire grid 10 is high, and the light emitted by the light-emitting device 42 has substantially the same polarization direction, and the light-extraction efficiency of the light-emitting device 42 is high. In a case where the light-emitting device 42 is applied to the backlight module 40 and the display apparatus 1, it may be possible to increase the light extraction efficiency of the backlight module 40 and reduce the power consumption of the display apparatus 1.

In some embodiments, as shown in FIG. 9, the metal wire grid 10 includes a first metal layer 11, a light-transmitting medium layer 12 and a second metal layer 13.

In some examples, the first metal layer 11 includes a plurality of first metal patterns 110. Each first metal pattern 110 extends in the first direction X. The plurality of first metal patterns 110 are arranged at intervals in the second direction Y. The first direction X and the second direction Y intersect. For example, an angle between the first direction X and the second direction Y is 85°, 90°, 95°, 100°, or 105°.

For convenience of the description, the embodiments of the present disclosure are described by taking an example in which the angle between the first direction X and the second direction Y is 90°.

For example, there is a gap between any two adjacent first metal patterns 110, and any two adjacent first metal patterns 110 are parallel to each other.

For example, the first metal layer 11 may be located on a side of the first semiconductor layer 43 away from the second semiconductor layer 45.

In some examples, the light-transmitting medium layer 12 includes a plurality of light-transmitting medium patterns 120. Each light-transmitting medium pattern 120 extends in the first direction X. The plurality of light-transmitting medium patterns 120 are arranged at intervals in the second direction Y.

For example, a light-transmitting medium pattern 120 is located between two adjacent first metal patterns 110.

For example, the light-transmitting medium pattern 120 separates two adjacent first metal patterns 110.

In some examples, the second metal layer 13 includes a plurality of second metal patterns 130. Each second metal pattern 130 extends in the first direction X. The plurality of second metal patterns 130 are arranged at intervals in the second direction Y. A second metal pattern 130 is located on a surface of a light-transmitting medium pattern 120 close to the first semiconductor layer 43.

For example, the plurality of second metal patterns 130 and the plurality of light-transmitting medium patterns 120 are in a one-to-one correspondence.

For example, a thickness of the light-transmitting medium pattern 120 is greater than a thickness of the first metal pattern 110. The second metal pattern 130 is not connected to an adjacent first metal pattern 110, and there is a gap between the second metal pattern 130 and the first metal pattern 110, so that the light emitted by the light-emitting layer 44 may pass through the metal wire grid 10 via the gap and the light-transmitting medium pattern 120. Therefore, the transmittance of the metal wire grid 10 is increased, and the light extraction efficiency of the light-emitting device 42 is improved. In addition, the TE light reflected on the metal wire grid 10 is incident on the phase deflection layer 46 and then converted into TM light, and then is incident on the metal wire grid 10 again and passes through the metal wire grid 10. Thereby, the amount of single-polarization light passing through the metal wire grid 10 is large, and the degree of polarization of the light emitted from the metal wire grid 10 is increased. As a result, the light-emitting device 42 emits light of a single polarization state.

It will be noted that the thickness of the light-transmitting medium pattern 120 refers to a size of the light-transmitting medium pattern 120 in a Z direction as shown in FIG. 9. Similarly, the thickness of the first metal pattern 110 refers to a size of the first metal pattern 110 in the Z direction as shown in FIG. 9.

It will be understood that a shape of the first metal pattern 110 and a shape of the second metal pattern 130 may be set according to actual conditions, which will not be limited in the present disclosure.

In some examples, as shown in FIG. 9, along a direction perpendicular to a plane where the metal wire grid 10 is located and in the second direction Y, a shape of a section of the first metal pattern 110 includes an upright trapezoid.

For example, the Z direction in FIG. 9 is a thickness direction of the metal wire grid 10, i.e., the direction perpendicular to the plane where the metal wire grid 10 is located.

For example, in the sectional view of the metal wire grid 10 shown in FIG. 9, the section of the first metal pattern 110 is in a shape of an upright trapezoid, so that a thickness of an edge of the first metal pattern 110 is small. In this way, a section of a light-transmitting medium pattern 120 adjacent to the first metal pattern 110 is in a shape of an inverted trapezoid, which may effectively prevent a material of the second metal pattern from climbing down along a sidewall of the light-transmitting medium pattern 120. Therefore, it may be possible to reduce the risk of contact between edges of the first metal pattern 110 and the adjacent second metal pattern 130, avoid the contact between the first metal pattern 110 and the adjacent second metal pattern 130, avoid a seamless whole structure formed by the first metal pattern and the second metal pattern, and avoid that the whole structure causes light cannot pass through the metal wire grid. As a result, it may be possible to improve the light transmittance of the metal wire grid 10, and in turn improve the light extraction efficiency of the light-emitting device 42 and the light extraction efficiency of the backlight module 40. In addition, the sidewall of the first metal pattern 110 is designed in a slope shape, which may improve the light transmittance of the metal wire grid 10 to a certain extent.

In some other examples, as shown in FIG. 10, along the direction perpendicular to the plane where the metal wire grid 10 is located and in the second direction Y, a shape of a section of the second metal pattern 130 includes an upright trapezoid.

For example, in the sectional view of the light-emitting device 42 shown in FIG. 10, the section of the second metal pattern 130 is in a shape of an upright trapezoid, so that a thickness of an edge of the second metal pattern 130 is small. In this way, in a process of forming the second metal pattern 130, it may effectively prevent the material of the second metal pattern from climbing down along a sidewall of an adjacent light-transmitting medium pattern 120. Therefore, it may be possible to reduce the risk of contact between edges of the second metal pattern 130 and the first metal pattern 110, avoid the contact between the first metal pattern 110 and the second metal pattern 130, avoid a seamless whole structure formed by the first metal pattern and the second metal pattern, and avoid that the whole structure causes light cannot pass through the metal wire grid. As a result, it may be possible to improve the light transmittance of the metal wire grid 10, improve the degree of polarization of the light emitted from the light-emitting device 42, and in turn improve the light extraction efficiency of the light-emitting device 42 and the light extraction efficiency of the backlight module 40.

It will be noted that the degree of polarization of the light emitted from the light-emitting device 42 refers to a ratio of a difference between the TM light passing through the metal wire grid 10 and the TE light reflected on the metal wire grid 10 to the light incident on the metal wire grid 10. Therefore, the greater the light transmittance of the metal wire grid 10, the greater the degree of polarization of the light emitted from the light-emitting device 42.

It will be understood that in the case where one of the section of the first metal pattern 110 and the section of the second metal pattern 130 is in a shape of an upright trapezoid, the other one of the section of the first metal pattern 110 and the section of the second metal pattern 130 may be in a shape of a rectangle.

In yet some other examples, as shown in FIG. 9, along the direction perpendicular to the plane where the metal wire grid 10 is located and in the second direction Y, the shape of the section of the first metal pattern 110 includes an upright trapezoid, and the shape of the section of the second metal pattern 130 includes an upright trapezoid.

In this way, the risk of contact between the first metal pattern 110 and the second metal pattern 130 may be reduced, so that the gap between the first metal pattern 110 and the second metal pattern 130 is increased to a certain extent. Therefore, the light transmittance of the metal wire grid 10 is increased, the degree of polarization of the light emitted from the light-emitting device 42 is improved, and the light extraction efficiency of the light-emitting device 42 and the light extraction efficiency of the backlight module 40 are improved.

In some embodiments, as shown in FIG. 9, along the direction perpendicular to the plane where the metal wire grid 10 is located and in the second direction Y, a shape of a section of the light-transmitting medium pattern 120 includes an inverted trapezoid.

Since the second metal pattern 130 is located on the light-transmitting medium pattern 120 and the shape of the section of the light-transmitting medium pattern 120 includes an inverted trapezoid, during the process of forming the second metal patterns 130, it may be possible to reduce the risk of the material of the second metal layer climbing on the sidewall of the light-transmitting medium pattern 120, and reduce the risk of the second metal pattern 130 coming into contact with the adjacent first metal pattern 110 along the sidewall of the light-transmitting medium pattern 120. Thus, the disconnection between the first metal pattern 110 and the second metal pattern 130 may be guaranteed to a certain extent. As a result, it may be possible to increase the light transmittance of the metal wire grid 10, reduce the absorptivity of the metal wire grid 10, increase the degree of polarization of the light-emitting device 42, and improve the light extraction efficiency of the light-emitting device 42 and the light extraction efficiency of the backlight module 40.

It will be understood that in the sectional view of the metal wire grid 10 in FIG. 9, due to process errors and the like, the sections of the first metal pattern 110, the second metal pattern 130 and the light-transmitting medium pattern 120 may not be in a shape of a sharp upright trapezoid or a sharp rectangle. For example, upper or lower angles of the trapezoid may be arc angles or approximately arc angles (not shown in FIG. 9), and four angles of the rectangle may be arc angles or approximately arc angles. In addition, the above-mentioned upright trapezoid is related to the viewing angle of the metal wire grid 10 or the placement of the metal wire grid 10. For example, in the sectional view of the light-emitting device of a flip-chip structure shown in FIG. 9, the above-mentioned upright trapezoid means that the shape of the section of the first metal pattern in the metal wire grid 10 is an upright trapezoid when viewed in a direction of the second metal pattern 130 pointing toward the first metal pattern 110.

In some examples, as shown in FIG. 9, in the second direction Y, a distance between any two adjacent first metal patterns 110 is substantially equal, and a distance between any two adjacent second metal patterns 130 is substantially equal.

For example, the distance between any two adjacent first metal patterns 110 is equal, and the distance between any two adjacent second metal patterns 130 is equal.

Since the distance between any two adjacent first metal patterns 110 in the second direction Y is substantially equal and the light-transmitting medium pattern 120 may be in contact with the two adjacent first metal patterns 110, sizes of any two adjacent light-transmitting medium patterns 120 in the second direction Y may be equal. Alternatively, the light-transmitting medium pattern 120 may not be in contact with the adjacent first metal pattern 110; in this case, the sizes of any two adjacent light-transmitting medium patterns 120 in the second direction Y may be equal, or may not be equal.

Since the distance between any two adjacent first metal patterns 110 in the second direction Y is substantially equal and two adjacent second metal patterns 130 are respectively located on corresponding light-transmitting medium patterns 120, the second metal pattern 130 may completely cover the corresponding light-transmitting medium pattern 120, and sizes of the second metal pattern 130 and the corresponding light-transmitting medium pattern 120 in the second direction Y may be equal.

In this way, the light-transmitting medium patterns 120 and the first metal patterns 110 as well as the second metal patterns 130 may be arranged periodically or regularly, thereby simplifying the fabrication process of the light-transmitting medium layer 12 and reducing the manufacturing difficulty of the metal wire grid 10 and the light-emitting device 42. In addition, since the light-transmitting medium patterns 120 and the first metal patterns 110 as well as the second metal patterns 130 are arranged periodically or regularly, it may be possible to ensure that the metal wire grid 10 can transmit light in a particular wavelength range (such as light in a visible light wavelength range), and in turn ensure the uniformity of the wavelength of the light passing through the metal wire grid 10.

In some other examples, the size of each first metal pattern 110 in the second direction Y is substantially equal, and the size of each second metal pattern 130 in the second direction Y is substantially equal.

For example, from a top view perspective, each first metal pattern 110 may be in a shape of a strip, and the size of the first metal pattern 110 in the second direction Y refers to an average size of the strip in a width direction. Similarly, from a top view perspective, each second metal pattern 130 may also be in a shape of a strip, and the size of the second metal pattern 130 in the second direction Y refers to an average size of the strip in a width direction.

In this way, it may be possible to reduce the fabrication difficulty of the first metal layer 11 and the second metal layer 13 and reduce the manufacturing difficulty of the metal wire grid 10 and the light-emitting device 42. In addition, it may also be possible to increase the light transmittance of the metal wire grid 10 to a certain extent and reduce the absorptivity of the metal wire grid 10, and in turn improve the light extraction efficiency of the light-emitting device 42 and the light extraction efficiency of the backlight module 40.

In yet some other examples, in the second direction Y, the distance between any two adjacent first metal patterns 110 is substantially equal, and the distance between any two adjacent second metal patterns 130 is substantially equal; and the size of each first metal pattern 110 in the second direction Y is substantially equal, and the size of each second metal pattern 130 in the second direction Y is substantially equal.

For example, a plurality of first metal patterns 110 continuously arranged are arranged at equal intervals, and a plurality of second metal patterns 130 that are continuously arranged are arranged at equal intervals.

In this way, the first metal patterns 110, the second metal patterns 130 and the light-transmitting medium patterns 120 in the metal wire grid 10 may be arranged periodically and in a regular manner, which facilitates the manufacturing of the metal wire grid 10 and the light-emitting device 42, and in turn reduces the manufacturing difficulty of the light-emitting device 42. In addition, the light transmittance of the metal wire grid 10 may be increased, so that the consistency of the polarization direction of the light emitted from the light-emitting device 42 is improved, and the degree of polarization of light emitted from the light-emitting device 42 and the backlight module 40 and the light extraction efficiency of the light-emitting device 42 and the backlight module 40 are improved.

In some embodiments, the first metal layer 11 and the second metal layer 13 may be made of the same material.

For example, any one of the first metal layer 11 and the second metal layer 13 may be made of a metal material such as aluminum (Al), silver (Ag), gold (Au), copper (Cu), etc.

Since the first metal layer 11 and the second metal layer 13 are made of the above-mentioned metal material, the metal wire grid 10 may have a low absorptivity and a high light transmittance, which may improve the light extraction efficiency of the light-emitting device 42 and the degree of polarization of the light emitted from the light-emitting device 42.

For example, the first metal layer 11 and the second metal layer 13 may both be made of aluminum. Compared with other metal materials, aluminum has high light transmittance to light in the visible light wavelength range, low absorptivity and low cost.

Since the first metal layer 11 and the second metal layer 13 are made of aluminum, it may be possible to further increase the light transmittance of the metal wire grid 10 and further reduce the absorptivity. As a result, the light extraction efficiency of the light-emitting device 42 and the degree of polarization of the light emitted from the light-emitting device 42 may be improved, the manufacturing cost of the metal wire grid 10 is significantly lower, and the cost of the light-emitting device 42 and the backlight module 40 is also reduced.

It will be understood that the size of the first metal pattern 110 and the size of the second metal pattern 130 may be set according to the actual situations, which will not be limited in the present disclosure. In some examples, the size of the first metal pattern 110 in the second direction Y is in a range of 50 nm to 70 nm.

For example, the size of the first metal pattern 110 in the second direction Y may be in a range of 50 nm to 60 nm, or may be in a range of 60 nm to 70 nm.

For example, the size of the first metal pattern 110 in the second direction Y may be 50 nm, 55 nm, 60 nm, 65 nm, or 70 nm.

In some other examples, the size of the second metal pattern in the second direction is in a range of 50 nm to 70 nm.

For example, the size of the second metal pattern 130 in the second direction Y may be in a range of 50 nm to 60 nm, or may be in a range of 60 nm to 70 nm.

For example, the size of the second metal pattern 130 in the second direction Y may be 50 nm, 55 nm, 60 nm, 65 nm, or 70 nm.

In yet some other examples, the size of the first metal pattern 110 in the second direction Y may be in the same range as the size of the second metal pattern 130 in the second direction Y. The size of the first metal pattern 110 in the second direction Y is in a range of 50 nm to 70 nm, and the size of the second metal pattern in the second direction is in a range of 50 nm to 70 nm.

For example, the size of the first metal pattern 110 in the second direction Y and the size of the second metal pattern 130 in the second direction Y may be equal. Alternatively, the size of the first metal pattern 110 in the second direction Y and the size of the second metal pattern 130 in the second direction Y may not be equal.

For example, the size of the first metal pattern 110 in the second direction Y may be 60 nm, and the size of the second metal pattern 130 in the second direction Y may be 65 nm.

In order to explore the effect of various parameters of the metal wire grid 10 in the light-emitting device 42 (such as the size of the first metal pattern, the size of the second metal pattern, the size and refractive index of the light-transmitting medium pattern, etc.) on the light transmittance, absorptivity, degree of polarization, etc. of the metal wire grid 10, the inventors of the present disclosure conducted simulation experiments on various parameters of the metal wire grid 10.

Considering an example in which the size of the first metal pattern 110 in the second direction Y and the size of the second metal pattern 130 in the second direction Y are equal, the inventors have simulated the relationship between the size of the first metal pattern 110 (or the second metal pattern 130) in the second direction Y and the light transmittance as well as the absorptivity of the metal wire grid 10. In the specific simulation, parameters of the metal wire grid 10 and the corresponding light-emitting device 42 are as follows. The first metal layer 11 and the second metal layer 13 are both made of aluminum. The thicknesses of the first metal pattern 110 and the thicknesses of the second metal pattern 130 are both 50 nm. The refractive index of the light-transmitting medium layer 12 is 1.5. The thickness of the light-transmitting medium pattern 120 is 70 nm. The distance between two adjacent light-transmitting medium patterns in the second direction is 60 nm. A connection layer is provided between the first metal layer 11 and the first semiconductor layer, a refractive index of the connection layer is 1.5, and a thickness of the connection layer is 150 nm. A refractive index of the first semiconductor layer through which the light emitted by the light-emitting layer passes is 2.4. The sizes of the first metal pattern and the second metal pattern in the second direction Y are equal, and the size of the first metal pattern 110 (or the second metal pattern 130) in the second direction Y is set to be between 10 nm and 120 nm. The light emitted by the light-emitting layer 44 exiting from the metal wire grid 10 after passing through the connection layer is monitored. A curve graph shown in FIG. 11 is obtained with the size of the first metal pattern 110 in the second direction Y as an abscissa and the light transmittance and absorptivity of the metal wire grid 10 as an ordinate.

It can be seen from FIG. 11 that as the size of the first metal pattern 110 (or the second metal pattern 130) in the second direction Y gradually increases, the absorptivity of the metal wire grid 10 first shows a small increase to about 0.50 and then decreases to about 0.15, and then continues to decrease gently. As the size of the first metal pattern 110 (or the second metal pattern 130) in the second direction Y gradually increases, the light transmittance of the metal wire grid 10 first increases to a peak (the peak of the light transmittance is about 0.85, where the size of the first metal pattern 110 in the second direction Y is 60 nm), and then decreases. In the case where the size of the first metal pattern 110 in the second direction Y is 120 nm, the light transmittance of the metal wire grid 10 is 0, and the metal wire grid 10 is opaque.

Referring to FIG. 11, in the case where the size of the first metal pattern 110 in the second direction Y is set to be in a range of 50 nm to 70 nm and/or the size of the second metal pattern in the second direction is set to be in a range of 50 nm to 70 nm, the light transmittance of the metal wire grid 10 in the light-emitting device 42 is greater than 70%, and the absorptivity is less than 22%. The metal wire grid 10 has a relatively high light transmittance and a relatively low absorptivity, thereby improving the light extraction efficiency of the light-emitting device 42 and the light extraction efficiency of the backlight module 40 and reducing the power consumption of the display apparatus 1.

In some examples, the thickness of the first metal pattern 110 is in a range of 50 nm to 60 nm; and/or the thickness of the second metal pattern is in a range of 50 nm to 60 nm.

For example, the thickness of the first metal pattern is 50 nm, 52 nm, 55 nm, 57 nm, or 60 nm.

For example, the thickness of the second metal pattern is 50 nm, 53 nm, 56 nm, 58 nm, or 60 nm.

In some examples, the thickness of the second metal pattern 130 is equal to the thickness of the first metal pattern 110.

For example, the thickness of the second metal pattern 130 and the thickness of the first metal pattern 110 are both 60 nm.

For another example, the thickness of the second metal pattern 130 and the thickness of the first metal pattern 110 are both 55 nm.

Since the thickness of the first metal pattern is equal to the thickness of the second metal pattern, it may facilitate the design of the metal wire grid 10. As a result, it may be possible to reduce the fabrication difficulty of the first metal layer 11 and the second metal layer 13, and reduce the manufacturing difficulty of the metal wire grid 10 and the light-emitting device 42.

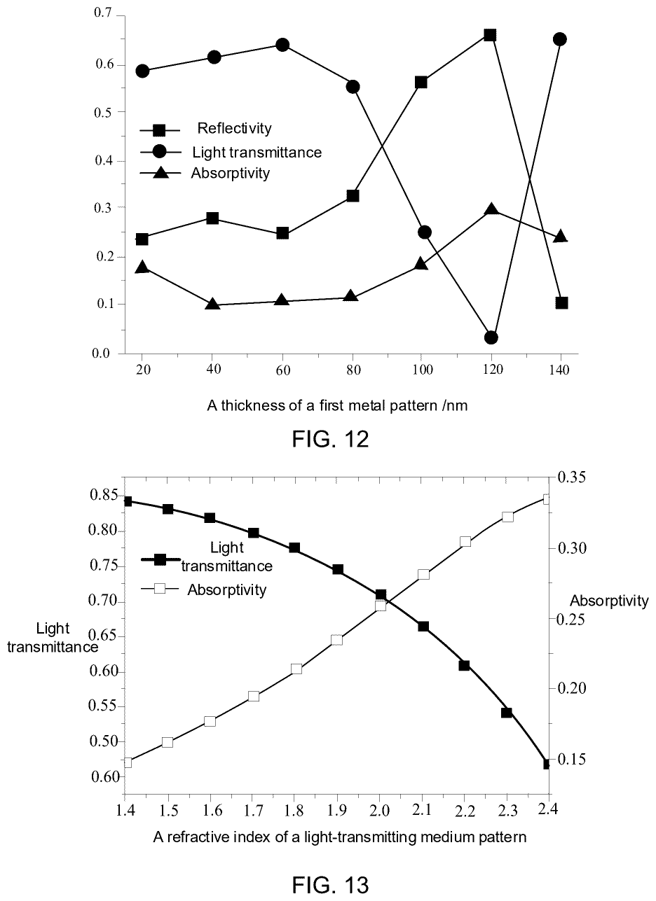

Considering an example in which the thickness of the first metal pattern 110 is equal to the thickness of the second metal pattern 130, the inventors have simulated the relationship between the thickness of the first metal pattern 110 (or the second metal pattern 130) and the light transmittance, absorptivity and reflectivity of the metal wire grid 10. In the specific simulation, parameters of the metal wire grid 10 and the corresponding light-emitting device 42 are as follows. The first metal layer 11 and the second metal layer 13 are both made of aluminum. The refractive index of the light-transmitting medium layer 12 is 1.5. The thickness of the light-transmitting medium pattern 120 is 80 nm. The distance between two adjacent light-transmitting medium patterns 120 in the second direction Y is 60 nm. A connection layer is provided between the first metal layer 11 and the first semiconductor layer, a refractive index of the connection layer is 1.5, and a thickness of the connection layer is 100 nm. A refractive index of a base (the base is made of silicon dioxide (SO₂)) through which the light emitted by the light-emitting layer passes is 1.5. The sizes of the first metal pattern 110 and the second metal pattern 130 in the second direction Y are equal to 60 nm. The thickness of the first metal pattern 110 is the same as the thickness of the second metal pattern 130. The thickness of the first metal pattern 110 (or the second metal pattern 130) is set to be between 20 nm and 140 nm. The light emitted by the light-emitting layer 44 exiting from the metal wire grid 10 after passing through the base is monitored. A curve graph shown in FIG. 12 is obtained with the thickness of the first metal pattern 110 as an abscissa and the light transmittance, absorptivity and reflectivity of the metal wire grid 10 as an ordinate.

It can be seen from FIG. 12 that as the thickness of the first metal pattern 110 (or the second metal pattern 130) gradually increases, the absorptivity of the metal wire grid 10 first shows a small decrease to about 0.1 and then increases to about 0.3, and then continues to decrease. As the thickness of the first metal pattern 110 (or the second metal pattern 130) gradually increases, the light transmittance of the metal wire grid 10 first increases gently to about 0.65, then decreases to about 0.02, and then starts to increase. The reflectivity and light transmittance of the metal wire grid 10 have substantially opposite trends. As the thickness of the first metal pattern 110 (or the second metal pattern 130) gradually increases, the reflectivity of the metal wire grid 10 first increases gently to about 0.27 and then decreases to about 0.25, and then increases to 0.67 and then decreases. In the case where the thickness of the first metal pattern 110 is 120 nm, the light transmittance of the metal wire grid 10 is minimum, and the reflectivity of the metal wire grid 10 is maximum.

Referring to FIG. 12, in the case where the thickness of the first metal pattern 110 is set to be in a range of 50 nm to 60 nm and/or the thickness of the second metal pattern is set to be in a range of 50 nm to 60 nm, the light transmittance of the metal wire grid 10 in the light-emitting device 42 is greater than 60%, and the absorptivity is less than 15%. The metal wire grid 10 has a relatively high light transmittance and a relatively low absorptivity, thereby improving the light extraction efficiency of the light-emitting device 42 and the light extraction efficiency of the backlight module 40 and reducing the power consumption of the display apparatus 1.

In some examples, the refractive index of the light-transmitting medium pattern 120 is in a range of 1.4 to 1.5.

For example, the refractive index of the light-transmitting medium pattern 120 is 1.40, 1.43, 1.46, 1.48, or 1.50.

The inventors have simulated the relationship between the refractive index of the light-transmitting medium pattern 120 and the light transmittance and absorptivity of the metal wire grid 10. In the specific simulation, parameters of the metal wire grid 10 and the corresponding light-emitting device 42 are as follows. The first metal layer 11 and the second metal layer 13 are both made of aluminum. The thickness of the first metal pattern 110 and the thickness of the second metal pattern 130 are both 50 nm. The thickness of the light-transmitting medium pattern 120 is 80 nm. The distance between two adjacent light-transmitting medium patterns 120 in the second direction Y is 60 nm. A connection layer is provided between the first metal layer 11 and the first semiconductor layer, a refractive index of the connection layer is 1.5, and a thickness of the connection layer is 150 nm. A refractive index of the first semiconductor layer (the first semiconductor layer is made of gallium nitride (GaN)) through which the light emitted by the light-emitting layer 44 passes is 2.4. The sizes of the first metal pattern and the second metal pattern in the second direction Y are equal to 60 nm. The thickness of the first metal pattern 110 is the same as the thickness of the second metal pattern 130. The refractive index of the light-transmitting medium pattern 120 is set to be between 1.4 and 2.4. The light emitted by the light-emitting layer 44 exiting from the metal wire grid after passing through the first semiconductor layer 43 and the connection layer is monitored. A curve graph shown in FIG. 13 is obtained with the refractive index of the light-transmitting medium pattern 120 as an abscissa and the light transmittance and absorptivity of the metal wire grid 10 as an ordinate.

It can be seen from FIG. 13 that as the refractive index of the light-transmitting medium pattern 120 gradually increases, the absorptivity of the metal wire grid 10 gradually increases, and the light transmittance of the metal wire grid 10 gradually decreases. In the case where the refractive index of the light-transmitting medium pattern 120 is 1.4, the metal wire grid 10 has a maximum light transmittance of about 0.84 and a minimum absorptivity of about 0.47.

Referring to FIG. 13, in the case where the refractive index of the light-transmitting medium pattern 120 is set to be in a range of 1.4 to 1.5, the light transmittance of the metal wire grid 10 in the light-emitting device 42 is greater than 80%, and the absorptivity is less than 48%. The metal wire grid 10 has a relatively high light transmittance and a relatively low absorptivity, thereby improving the light extraction efficiency of the light-emitting device 42 and the light extraction efficiency of the backlight module 40 and reducing the power consumption of the display apparatus 1.

In some examples, a ratio of the thickness of the light-transmitting medium pattern 120 to the thickness of the first metal pattern 110 is in a range of 1.17 to 1.60.

For example, the ratio of the thickness of the light-transmitting medium pattern 120 to the thickness of the first metal pattern 110 may be 1.17, 1.20, 1.30, 1.45 or 1.60.

For example, when the thickness of the first metal pattern 110 is in a range of 50 nm to 60 nm, the thickness of the light-transmitting medium pattern 120 may be in a range of 70 nm to 80 nm.

In this way, the surface of the light-transmitting medium pattern 120 is not flush with the surface of the first metal pattern 110, so that the light-transmitting medium pattern 120 is higher than the first metal pattern 110. Therefore, the disconnection between the first metal pattern 110 and the adjacent second metal pattern 130 may be guaranteed to a certain extent, and the risk of connection between the first metal pattern 110 and the second metal pattern 130 on the light-transmissive medium pattern 120 is reduced.

In some other examples, a ratio of the thickness of the light-transmitting medium pattern 120 to the thickness of the second metal pattern 130 is in a range of 1.17 to 1.60.

For example, the ratio of the thickness of the light-transmitting medium pattern 120 to the thickness of the second metal pattern 130 may be 1.17, 1.20, 1.30, 1.40, or 1.60.

For example, when the thickness of the second metal pattern 130 is in a range of 50 nm to 60 nm, the thickness of the light-transmitting medium pattern 120 may be in a range of 70 nm to 80 nm.

In yet some other examples, the ratio of the thickness of the light-transmitting medium pattern 120 to the thickness of the first metal pattern 110 is in a range of 1.17 to 1.60, and the ratio of the thickness of the light-transmitting medium pattern 120 to the thickness of the second metal pattern 130 is in a range of 1.17 to 1.60.

For example, the thickness of the first metal pattern 110 may be the same as the thickness of the second metal pattern 130. In this way, the ratio of the thickness of the light-transmitting medium pattern 120 to the thickness of the first metal pattern 110 may be the same as the ratio of the thickness of the light-transmitting medium pattern 120 to the thickness of the second metal pattern 130.

In the case where the thickness of the first metal pattern 110 is in a range of 50 nm to 60 nm and the thickness of the second metal pattern 130 is in a range of 50 nm to 60 nm, the thickness of the light-transmitting medium pattern 120 is in a range of 70 nm to 80 nm.

For example, the thickness of the light-transmitting medium pattern 120 may be 70 nm, 73 nm, 75 nm, 78 nm, or 80 nm.

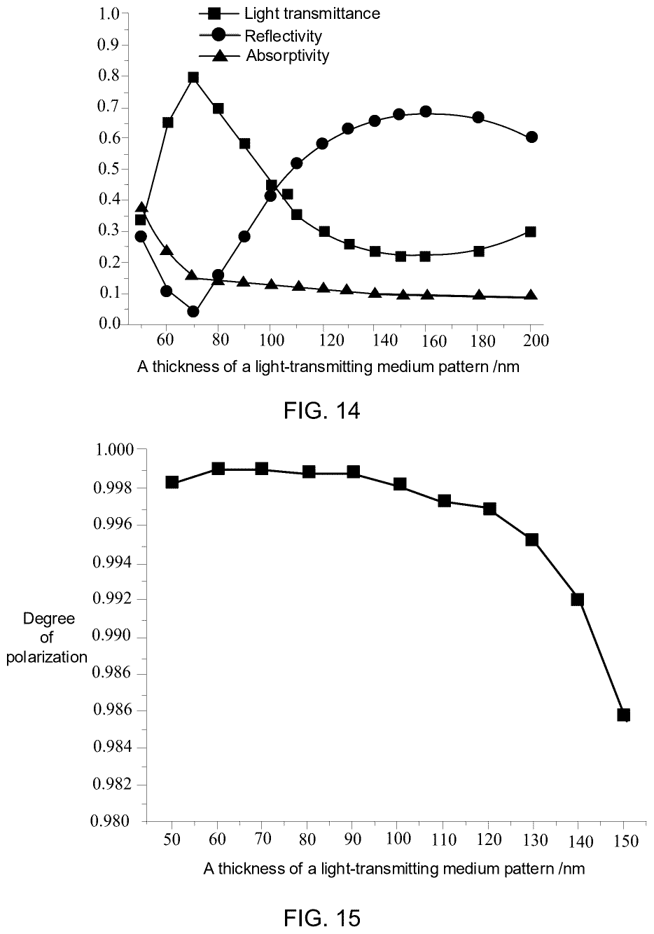

The inventors have simulated the relationship between the thickness of the light-transmitting medium pattern 120 and the light transmittance, reflectivity and degree of polarization of the metal wire grid 10. In the specific simulation, parameters of the metal wire grid 10 and the corresponding light-emitting device 42 are as follows. The first metal layer 11 and the second metal layer 13 are both made of aluminum. The thickness of the first metal pattern 110 and the thickness of the second metal pattern 130 are both 50 nm. The refractive index of the light-transmitting medium pattern 120 is 1.5. The thickness of the light-transmitting medium pattern 120 is 80 nm. The distance between two adjacent light-transmitting medium patterns 120 in the second direction is 60 nm. A connection layer is provided between the first metal layer 11 and the first semiconductor layer, a refractive index of the connection layer is 1.5, and a thickness of the connection layer is 150 nm. A refractive index of the first semiconductor layer (the first semiconductor layer is made of GaN) through which the light emitted by the light-emitting layer passes is 2.4. The sizes of the first metal pattern and the second metal pattern in the second direction Y are equal to 60 nm. The thickness of the light-transmitting medium pattern 120 is set to be between 40 nm and 200 nm and between 40 nm and 150 nm. The light emitted by the light-emitting layer exiting from the metal wire grid after passing through the first semiconductor layer is monitored. A curve graph shown in FIG. 14 is obtained with the thickness of the light-transmitting medium pattern 120 as an abscissa and the light transmittance, absorptivity and reflectivity of the metal wire grid 10 as an ordinate. A curve graph shown in FIG. 15 is obtained with the thickness of the light-transmitting medium pattern 120 as an abscissa and the degree of polarization of the light emitted from the metal wire grid 10 as an ordinate.

It can be seen from FIG. 14 that as the thickness of the light-transmitting medium pattern 120 gradually increases, the light transmittance of the metal wire grid 10 first increases to about 0.80, then decreases and then increases gently; the reflectivity of the metal wire grid 10 first decreases, then increases and then decreases gently; and the absorptivity of the metal wire grid 10 gradually decreases. It can be seen from FIG. 15 that as the thickness of the light-transmitting medium pattern 120 gradually increases, the degree of polarization of the light emitted from the metal wire grid 10 decreases gently. In the case where the thickness of the light-transmitting medium pattern 120 is in a range of 60 nm to 100 nm, the degree of polarization of the light emitted from the metal wire grid 10 is greater than 99.98%.

Referring to FIGS. 14 and 15, in the case where the thickness of the light-transmitting medium pattern 120 is set to be in a range of 70 nm to 80 nm, the light transmittance of the metal wire grid 10 in the light-emitting device 42 is greater than 70%, the absorptivity is less than 15%, and the degree of polarization is greater than 99.98%, so that the metal wire grid 10 has a relatively high light transmittance, high degree of polarization, and relatively low absorptivity. Thus, it may be possible to improve the light extraction efficiency of the light-emitting device 42 and the light extraction efficiency of the backlight module 40, and reduce the power consumption of the display apparatus 1.

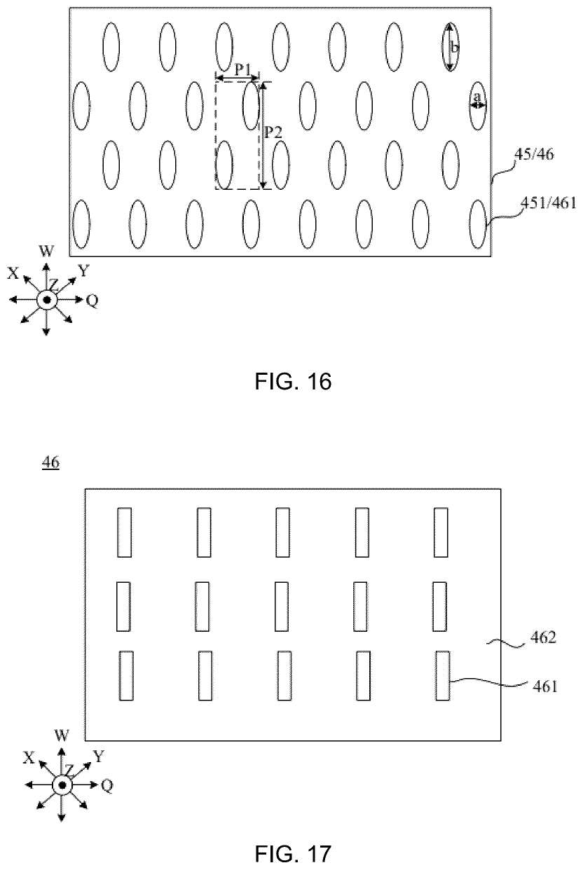

In some embodiments, as shown in FIG. 16, in the above-mentioned light-emitting device 42, the plurality of grooves 451 of the surface of the second semiconductor layer 45 away from the light-emitting layer 44 are arranged in a plurality of rows and a plurality of columns. Each row of grooves 451 is arranged in a third direction Q, and each column of grooves 451 is arranged in a fourth direction W. The third direction Q and the fourth direction W intersect, and the third direction Q and the fourth direction W are parallel to the plane where the metal wire grid 10 is located.

For example, the third direction Q has an angle with each of the first direction X and the second direction Y.

For example, a plane where the first direction X and the second direction Y are located is parallel to a plane where the third direction Q and the fourth direction W are located.

For example, an angle between the third direction Q and the fourth direction W is 85°, 90°, 95°, 100°, or 105°.

For convenience of the description, the angle between the third direction Q and the fourth direction W being 90° is taken as an example for introduction.

For example, a size of the groove 451 in the fourth direction W is greater than a size of the groove 451 in the third direction Q. The size of the groove 451 in the fourth direction W is different from the size of the groove 451 in the third direction Q.

In some examples, as shown in FIG. 9, the phase deflection layer 46 includes a plurality of first sub-portions 461 and a second sub-portion 462 connected to the plurality of first sub-portions 461. The first sub-portion 461 is located in the groove 451. The second sub-portion 462 is located outside the grooves 451 and located on a side of the second semiconductor layer 45 away from the metal wire grid 10.

The plurality of first sub-portions 461 and the second sub-portion 462 are connected to each other, so that the light emitted by the light-emitting layer 44 and incident on the phase deflection layer 46 and the light reflected by the metal wire grid 10 and incident on the phase deflection layer 46 are reflected on the phase deflection layer 46 and may be incident on the metal wire grid 10 again, which avoids unnecessary loss of the light emitted by the light-emitting layer 44 passing through the phase deflection layer 46, and in turn improves the light extraction efficiency of the light-emitting device 42.

For example, a distance between a surface of the first sub-portion 461 away from the light-emitting layer 44 and the light-emitting layer 44 is less than a distance between a surface of the second sub-portion 462 away from the light-emitting layer 44 and the light-emitting layer 44.

In this way, the whole phase deflection layer 46 may have ups and downs. When the light (TE light) reflected by the metal wire grid 10 is incident on the phase deflection layer 46, the light may undergo different reflections on different positions of the first sub-portions 461 of the phase deflection layer 46 and undergo phase delay to change the polarization direction (for example, the TE light is changed to the TM light), and then exits from the metal wire grid 10, thereby increasing the light extraction efficiency of the light-emitting device 42.

Since the first sub-portion 461 is located in the groove 451, the structure of the first sub-portion 461 of the phase deflection layer 46 is closely related to the structure of the groove 451. It will be understood that the corresponding structure of the first sub-portion 461 of the phase deflection layer 46 may be set according to actual needs, which will not be limited in the embodiments of the present disclosure.

For example, a thickness of the first sub-portion 461 may be the same as a thickness of the second sub-portion 462. For example, in the case where the light-emitting device 42 emits green light, the thickness of the first sub-portion 461 may be 150 nm.

In some embodiments, as shown in FIGS. 16 to 18, a shape of an orthographic projection of the first sub-portion 461 on the light-emitting layer 44 includes: rectangle, ellipse, and strip.

When the light (TE light) reflected by the metal wire grid 10 is incident on the phase deflection layer 46, the light may be reflected on the first sub-portions 461 of the phase deflection layer 46. The orthographic projection of the first sub-portion 461 on the light-emitting layer 44 is in a shape of a rectangle, an ellipse, or a strip shape. Considering the rectangle as an example, the light will undergo different reflections on longer and shorter sides of the rectangle, so that the light will undergo phase delay on the first sub-portion 461. The polarization direction of part of the light will be changed. For example, the part of the light changes from TE light to TM light. Then, the light will exits from the metal wire grid 10. Therefore, the light extraction efficiency of the light-emitting device 42 is increased. In addition, the first sub-portion 461 has a high polarization conversion rate for the above-mentioned light, which may further increase the light extraction efficiency of the light-emitting device 42.

For example, an angle between a direction of the major axis of the ellipse (for example, the fourth direction W) and an extending direction of the first metal pattern 110 of the metal wire grid 10 (for example, an extending direction of the second metal pattern 130 or the first direction X) may be an acute angle, such as 45°. In the case of the above-mentioned angle is 45°, the metal wire grid 10 and the first sub-portions 461 of the phase deflection layer 46 have the best cooperation effect. Therefore, a majority of the light (TE light) reflected by the metal wire grid 10 may undergo phase delay on the first sub-portion 461, and the polarization direction of the majority of the light is changed to be perpendicular to the transmission axis direction of the metal wire grid 10, which may greatly improve the polarization conversion rate of the first sub-portion 461.

For example, as shown in FIG. 16, in the case where the orthographic projection of the first sub-portion 461 on the light-emitting layer 44 is in a shape of an ellipse, and the angle between the direction of the major axis of the ellipse (for example, the fourth direction W) and the extending direction of the first metal pattern 110 of the metal wire grid 10 (for example, the extending direction of the second metal pattern 130 or the first direction X) is 45°, the polarization conversion rate of the first sub-portion 461 is simulated, and the polarization conversion rate of the first sub-portion 461 is 67%.

For another example, as shown in FIG. 17, in the case where the orthographic projection of the first sub-portion 461 on the light-emitting layer 44 is in a shape of a rectangle, and an angle between a direction of the longer side of the rectangle (for example, the fourth direction W) and the extending direction of the first metal pattern 110 of the metal wire grid 10 (for example, the extending direction of the second metal pattern 130 or the first direction X) is 45°, the polarization conversion rate of the first sub-portion 461 is simulated, and the polarization conversion rate of the first sub-portion is 76%.

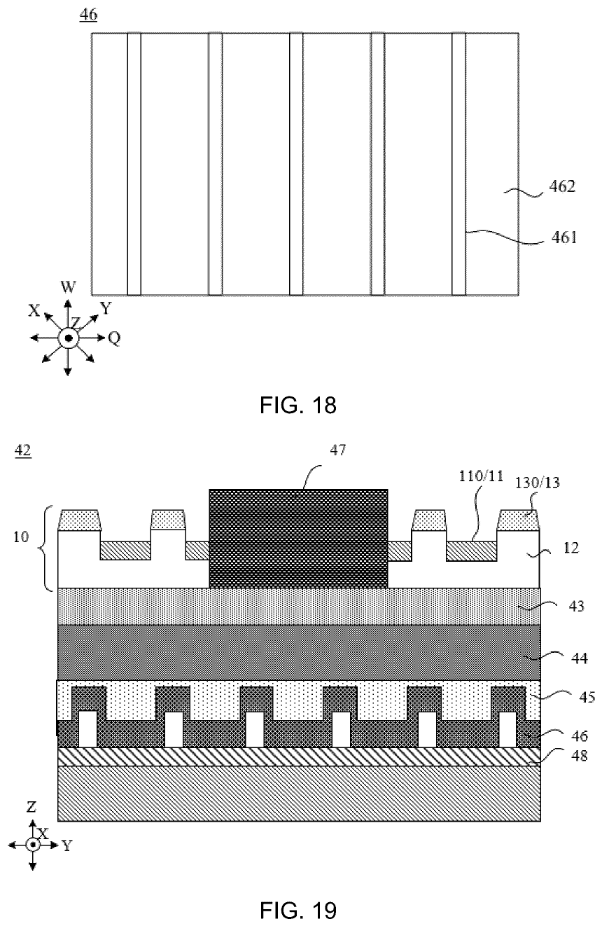

For yet another example, as shown in FIG. 18, in the case where the orthographic projection of the first sub-portion 461 on the light-emitting layer 44 is in a shape of a strip, and an angle between a direction of a longer side of the strip (for example, the fourth direction W) and the extending direction of the first metal pattern 110 of the metal wire grid 10 (for example, the extending direction of the second metal pattern 130 or the first direction X) is 45°, the polarization conversion rate of the first sub-portion 461 is simulated, and the polarization conversion rate of the first sub-portion 461 is 79%.

It can be seen that when the shape of the orthographic projection of the first sub-portion 461 on the light-emitting layer 44 varies, the polarization conversion rate of the first sub-portion 461 varies. In the case where a ratio of the longer side to the shorter side of the shape of the orthographic projection of the first sub-portion 461 on the light-emitting layer 44 is relatively large, the polarization conversion rate of the first sub-portion 461 is relatively high. Moreover, in the case where the orthographic projection of the first sub-portion 461 on the light-emitting layer 44 is in a shape of a strip, the polarization conversion rate of the first sub-portion 461 is the highest. Therefore, within the allowable manufacturing process range, the shape of the orthographic projection of the first sub-portion 461 on the light-emitting layer 44 may be set to be a strip shape to realize a higher polarization conversion rate of the first sub-portion 461.

In some examples, as shown in FIG. 16, the orthographic projection of the first sub-portion 461 on the light-emitting layer 44 is in a shape of an ellipse. The direction of the major axis of the ellipse may be parallel to the fourth direction W, and the direction of the minor axis of the ellipse may be parallel to the third direction Q. The shape of the first sub-portion 461 may be an elliptical cylinder. In the case where the light-emitting device 42 emits green light, a size a of the minor axis of the ellipse may be 110 nm, and a size b of the major axis of the ellipse is greater than or equal to 3a (b≥3a). For example, the size b of the major axis may be 330 nm, 350 nm, or 400 nm. A maximum distance, in the third direction Q, of a connection line between end points of minor axes of two adjacent ellipses in the fourth direction W is a first cycle P1 of the first sub-portion 461. A maximum distance, in the fourth direction W, of a connection line between end points of major axes of two adjacent ellipses in the fourth direction W is a second cycle P2 of the first sub-portion 461. For example, the first cycle P1 may be 250 nm, and the second cycle P2 may be 850 nm. The magnitudes of the first cycle P1 and the second cycle P2 will affect the polarization conversion rate of the first sub-portion 461. The first sub-portions 461 arranged based on the first cycle P1 and second cycle P2 may improve the polarization conversion rate of the phase deflection layer 46, thereby improving the light extraction efficiency of the light-emitting device 42.

It will be noted that when the orthographic projection of the first sub-portion 461 on the light-emitting layer 44 is in a shape of a rectangle or a strip, as for the sizes of the longer side and the shorter side, the relationship between the sizes of the longer side and the shorter side (for example, the size of the longer side is greater than or equal to 3 times the size of the shorter side), and parameters of the first period and the second period, reference may be made to the parameters of the ellipse mentioned above, and details will not be repeated here.

It will be understood that the polarization conversion rate of the phase deflection layer refers to a proportion of light that undergoes phase deflection and is converted into TM light in the light incident on the phase deflection layer. The higher the polarization conversion rate of the phase deflection layer 46 is, the greater the proportion of TE light reflected by the metal wire grid 10 that undergoes phase deflection on the phase deflection layer 46 and is converted into TM light. Thereby, the light transmittance of the metal wire grid 10 is relatively high, and the light extraction efficiency of the light-emitting device 42 and the light extraction efficiency of the backlight module 40 are relatively high.

In some embodiments, as shown in FIG. 9, the light-emitting device 42 further includes a first electrode 47 and a second electrode 48.

For example, the first electrode 47 is directly electrically connected to the first semiconductor layer 43, and provides a first voltage signal for the first semiconductor layer 43. The second electrode 48 is directly or indirectly electrically connected to the second semiconductor layer 45, and provides a second voltage signal for the second semiconductor layer 45.

It will be understood that the structural types of the light-emitting device 42 provided in the embodiments of the present disclosure include a normal structure, a flip-chip structure and a vertical structure.

In some embodiments, as shown in FIG. 9, the light-emitting device 42 has a flip-chip structure, and orthographic projections of the second semiconductor layer 45 and the light-emitting layer 44 on the plane where the metal wire grid 10 is located are located within an orthographic projection of the first semiconductor layer 43 on the plane where the metal wire grid 10 is located.

For example, the orthographic projections of the second semiconductor layer 45 and the light-emitting layer 44 on the plane where the metal wire grid 10 is located are located inside the orthographic projection of the first semiconductor layer 43 on the plane where the metal wire grid 10 is located. The orthographic projections of the second semiconductor layer 45 and the light-emitting layer 44 on the plane where the metal wire grid 10 is located partially coincides with the orthographic projection of the first semiconductor layer 43 on the plane where the metal wire grid 10 is located.

For example, the first electrode 47 is located on the side of the first semiconductor layer 43 away from the metal wire grid 10, and is electrically connected to a portion of the first semiconductor layer 43 extending beyond the light-emitting layer 44 and the second semiconductor layer 45.

In this way, it may be possible to ensure the accuracy of the first voltage signal transmitted by the first electrode 47 to the first semiconductor layer 43, and avoid interference with the first voltage signal caused by short circuit of the first electrode 47 with the second semiconductor layer 45 as well as the light-emitting layer 44.

For example, the second electrode 48 is located on a side of the phase deflection layer 46 away from the metal wire grid 10, and is electrically connected to the second semiconductor layer 45 through the phase deflection layer 46.

For example, the phase deflection layer 46 may be made of a conductive material, such as metal.

In this way, the second electrode 48 may be indirectly connected to the second semiconductor layer 45 through the phase deflection layer 46, which ensures that the second electrode 48 transmits the second voltage signal to the second semiconductor layer 45 and may reduce the light loss of the light-emitting device 42, avoids inevitable gap(s) in the phase deflection layer 46 caused by the need to form hole(s) in the phase deflection layer 46 to achieve electrical connection with the second semiconductor layer 45 during the process of forming the second electrode 48, and in turn avoids the light loss caused by the light incident on the phase deflection layer 46 exiting from the gap(s).

In the light-emitting device 42, the relative positional relationship between the first metal layer 11 and the second metal layer 13 of the metal wire grid 10 as well as the first semiconductor layer 43 varies, which may be selected according to needs.

In some examples, the second metal layer 13 is located on a side of the light-transmitting medium layer 12 close to the first semiconductor layer 43.

For example, the second metal layer 13 is closer to the first semiconductor layer 43 than the first metal layer 11.

In this way, during the process of manufacturing the light-emitting device 42, the metal wire grid 10 may be formed separately and then attached to an epitaxial structure, thereby improving the manufacturing efficiency of the light-emitting device 42, and avoiding a problem that forming the metal wire grid 10 after the epitaxial structure is formed causes a long manufacturing period of the light-emitting device 42.

In some other examples, as shown in FIG. 10, the first metal layer 11 is closer to the first semiconductor layer 43 than the second metal layer 13.

In yet some other examples, as shown in FIG. 10, the light-emitting device 42 further includes: a connection layer 61 located between the metal wire grid 10 and the first semiconductor layer 43. The second metal layer 13 is located on a side of the light-transmitting medium layer 12 close to the connection layer 61.

For example, the connection layer 61 is used to connect the epitaxial structure and the metal wire grid 10.

In this way, during the process of manufacturing the light-emitting device 42, the metal wire grid 10 may be directly integrated on the epitaxial structure, thereby dropping the process of attaching the metal wire grid 10 to the epitaxial structure, and in turn simplifying the manufacturing process of the light-emitting device 42.

It will be understood that in the case where the light-emitting device 42 is applied to the backlight module 40 or the light-emitting substrate, the light-emitting device 42 shown in FIGS. 9 and 10 needs to be turned upside down before being fixed. The metal wire grid 10 is located on the light-exit side of the light-emitting device 42.

In some other embodiments, as shown in FIG. 19, the light-emitting device 42 has a vertical structure, orthographic projections of the second semiconductor layer 45, the light-emitting layer 44 and the first semiconductor layer 43 on the plane where the metal wire grid 10 is located coincide or substantially coincide with each other.

For example, boundaries of orthographic projections of the second semiconductor layer 45, the light-emitting layer 44 and the first semiconductor layer 43 on the plane where the metal wire grid 10 is located at least partially coincide with each other.

For example, the first electrode 47 is located on a side of the first semiconductor layer 43 close to the metal wire grid 10, and is electrically connected to the first semiconductor layer 43 by penetrating the metal wire grid 10.

For example, the second electrode 48 is located on the side of the phase deflection layer 46 away from the metal wire grid 10, and is electrically connected to the second semiconductor layer 45 through the phase deflection layer 46.

In this way, the second electrode 48 may be indirectly connected to the second semiconductor layer 45 through the phase deflection layer 46, which ensures that the second electrode 48 transmits the second voltage signal to the second semiconductor layer 45 and may reduce the light loss of the light-emitting device 42, avoids inevitable gap(s) in the phase deflection layer 46 caused by the need to form hole(s) in the phase deflection layer 46 to achieve electrical connection with the second semiconductor layer 45 during the process of forming the second electrode 48, and in turn avoids the light loss caused by the light incident on the phase deflection layer 46 exiting from the gap(s).

For example, the second metal layer 13 is located on a side of the light-transmitting medium layer 12 away from the first semiconductor layer 43.

In this way, during the process of manufacturing the light-emitting device 42, the metal wire grid 10 may be directly integrated on the epitaxial structure, thereby dropping the process of attaching the metal wire grid 10 to the epitaxial structure, and in turn simplifying the manufacturing process of the light-emitting device 42.

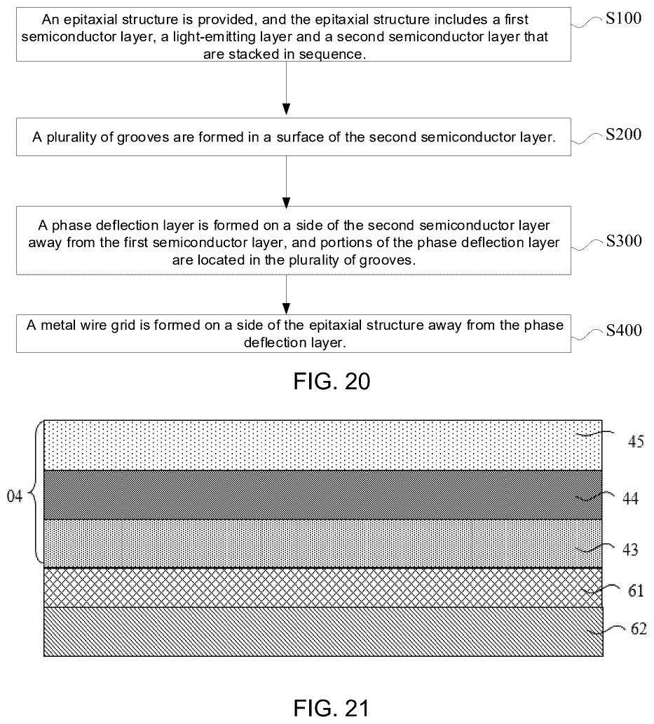

Some embodiments of the present disclosure further provide a method for manufacturing a light-emitting device 42. As shown in FIG. 20, the method includes S100 to S400.

In S100, as shown in FIG. 21, an epitaxial structure 04 is provided. The epitaxial structure 04 includes a first semiconductor layer 43, a light-emitting layer 44 and a second semiconductor layer 45 that are stacked in sequence.

For example, a thickness of the first semiconductor layer 43 may be 2000 nm, a thickness of the light-emitting layer 44 may be 50 nm, and a thickness of the second semiconductor layer 45 may be greater than 150 nm.

For example, a connection layer 61 is provided on a side of the epitaxial structure 04 close to the first semiconductor layer 43.

For example, the connection layer 61 is located on a side of the first semiconductor layer 43 away from the light-emitting layer 44.

For example, the connection layer 61 may be made of calcium nitride (CaN).

For example, a thickness of the connection layer 61 may be 2000 nm.

In some examples, a first base 62 is provided on a side of the connection layer 61 away from the first semiconductor layer 43.

For example, the first base 62 may be a sapphire base or silicon base.

For example, the first base 62 is used to provide support for the epitaxial structure 04.

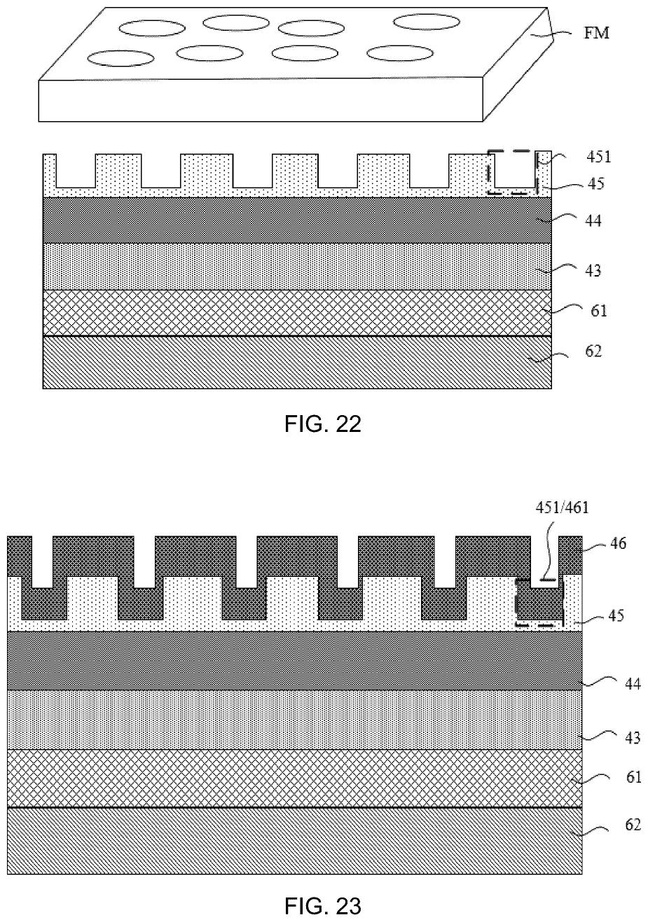

In S200, as shown in FIG. 22, a plurality of grooves 451 are formed in a surface of the second semiconductor layer 45.

For example, the plurality of grooves 451 may be formed in the surface of the second semiconductor layer 45 using a nanoimprint process.

For example, first, a side of the second semiconductor layer 45 away from the light-emitting layer 44 is coated with an imprinting film, and the imprinting film is imprinted using an imprinting template FM. The imprinting template has a plurality of patterns. When the imprinting film is imprinted using the imprinting template, the patterns of the imprinting template may be transferred to the imprinting film, so that a plurality of sub-grooves are formed in the imprinting film. Then, portions of the second semiconductor layer 45 corresponding to the plurality of sub-grooves are etched, the imprinting film is removed, and the plurality of grooves 451 are formed.

For example, the plurality of patterns of the imprinting template are in one-to-one correspondence with the grooves 451 to be formed. The arrangement and structural parameters of the plurality of grooves 451 to be formed may be adjusted by designing the arrangement of the plurality of patterns of the imprinting template, the structural parameters of the plurality of patterns, and etching parameters.

As for the arrangement and structural parameters of the plurality of grooves 451, reference may be made to the description of some of the above embodiments in the present disclosure, and details will not be repeated here.

In S300, as shown in FIG. 23, a phase deflection layer 46 is formed on a side of the second semiconductor layer 45 away from the first semiconductor layer 43, and portions of the phase deflection layer 46 are located in the plurality of grooves 451.

For example, the phase deflection layer 46 may be made of metal, such as silver (Ag).

For example, metallic silver may be deposited on an entire surface of the second semiconductor layer 45 away from the first semiconductor layer 43 using a sputtering process or an evaporation process, so as to form the phase deflection layer 46.

For example, the thickness of the phase deflection layer 46 may be 150 nm.

For example, the whole phase deflection layer 46 has a periodic wave shape. The surface of the phase deflection layer 46 close to the light-emitting layer 44 is uneven and is a non-flat surface.

In an implementation, a half-wave plate or a quarter-wave plate is used as a phase deflection structure, which is attached to the second semiconductor layer to achieve phase deflection of TE light. However, the attachment of the half-wave plate or quarter-wave plate causes complicated manufacturing processes of the light-emitting device and the backlight module and low manufacturing efficiency. In the method of manufacturing the light-emitting device 42 provided in some embodiments of the present disclosure, the phase deflection layer 46 is directly integrated on the second semiconductor layer 45, which simplifies the manufacturing process of the light-emitting device 42.

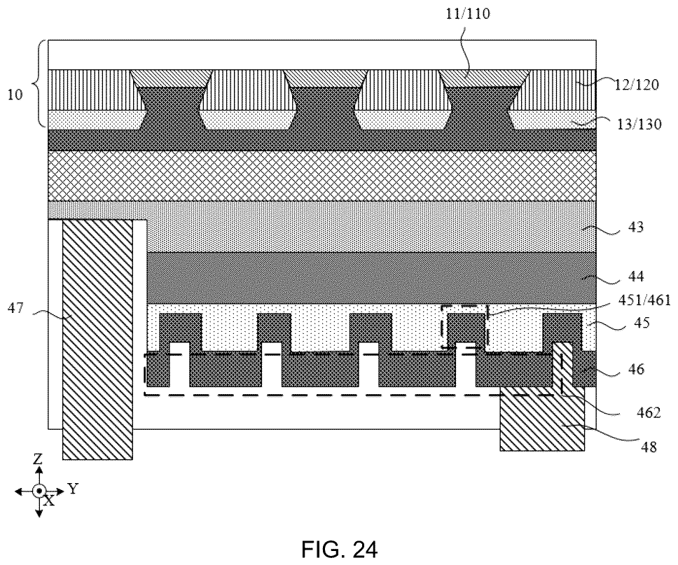

In S400, as shown in FIG. 24, a metal wire grid 10 is formed on a side of the epitaxial structure away from the phase deflection layer 46.

As for the structure of the metal wire grid 10, reference may be made to the description of some of the above embodiments of the present disclosure, and details will not be repeated here.

It will be understood that in FIG. 24, the metal wire grid 10 is formed after the epitaxial structure 04 is turned upside down.

The method of forming the metal wire grid 10 varies, which may be selected according to actual situations.

For example, the metal wire grid 10 is formed first, and then the metal wire grid 10 is bonded to the epitaxial structure 04 to form the light-emitting device 42.

For another example, the metal wire grid 10 may be directly integrated on the epitaxial structure 04.

In the method for manufacturing the light-emitting device 42 provided in some embodiments of the present disclosure, the epitaxial structure 04 is provided, and the plurality of grooves 451 are formed in the surface of the second semiconductor layer 45; then, the phase deflection layer 46 is formed, and the portions of the phase deflection layer 46 are located in the grooves 451; and the metal wire grid 10 is formed on the side of the phase deflection layer 46; therefore, the light-emitting device 42 is formed, and the manufacturing process of the light-emitting device 42 is simplified. In addition, TM light of light emitted by the epitaxial structure 04 may exit through the metal wire grid 10; and TE light of the light emitted by the epitaxial structure 04 is reflected by the metal wire grid 10 to the phase deflection layer 46 and undergoes phase delay at the phase deflection layer 46, the polarization direction of the TE light changes, and the TE light is converted into TM light and then exits through the metal wire grid 10. Thereby, the light transmittance and degree of polarization of the metal wire grid 10 are increased, the light loss of the light-emitting device 42 and the backlight module 40 is reduced, and the light extraction efficiency of the light-emitting device 42 and the backlight module 40 is improved. As a result, the power consumption of the display apparatus 1 is reduced.

For example, the metal wire grid 10 may have a single-layer wire grid structure or a double-layer wire grid structure.

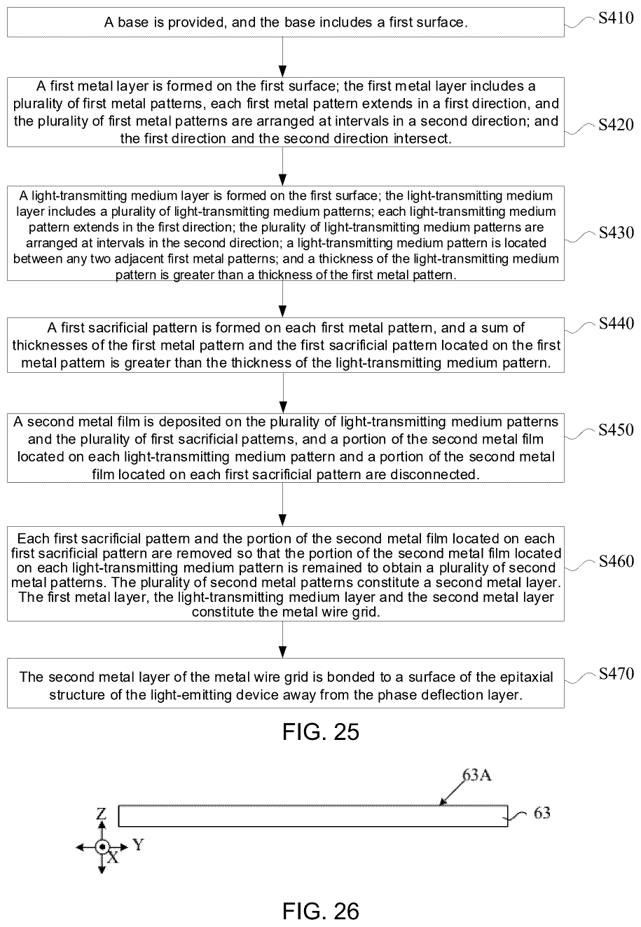

In some embodiments, as shown in FIG. 25, the above S400 in which the metal wire grid 10 is formed on the side of the epitaxial structure 04 away from the phase deflection layer 46 includes S410 to S470.

In S410, as shown in FIG. 26, a base 63 is provided. The base 63 includes a first surface 63A.

For example, the base 63 may be made of glass, sapphire, silicon wafer, etc.

For example, the base 63 may be of a flat plate-shaped structure.

In S420, as shown in FIGS. 26 to 29, a first metal layer 11 is formed on the first surface 63A; the first metal layer 11 includes a plurality of first metal patterns 110, each first metal pattern 110 extends in the first direction X, and the plurality of first metal patterns 110 are arranged at intervals in the second direction Y; and the first direction X and the second direction Y intersect.

For example, the method of forming the first metal layer 11 varies, which may be selected according to actual situations.

For example, as for the structure of the first metal patterns 110, reference may be made to the description of some of the above embodiments of the present disclosure, and details will not be repeated here.

For example, the first metal layer 11 may be made of aluminum, gold, silver, or may be made of an alloy composed of at least two of aluminum, gold, and silver.

In S430, as shown in FIGS. 30 and 31, a light-transmitting medium layer 12 is formed on the first surface 63A; the light-transmitting medium layer 12 includes a plurality of light-transmitting medium patterns 120; each light-transmitting medium pattern 120 extends in the first direction X; the plurality of light-transmitting medium patterns 120 are arranged at intervals in the second direction; a light-transmitting medium pattern 120 is located between any two adjacent first metal patterns; a thickness of the light-transmitting medium pattern 120 is greater than a thickness of the first metal pattern.

For example, the light-transmitting medium layer 12 may be made of a light-transmitting material, such as an organic resin material or an inorganic material. The organic resin material may be organic silicone resin or the like. The inorganic material may be silicon dioxide (SO₂), lithium fluoride (LiF), etc. Therefore, it may be possible to reduce the light loss of the light emitted by the light-emitting layer 44 when passing through the light-transmitting medium layer, and in turn improve the light transmittance of the metal wire grid 10.

For example, forming the light-transmitting medium layer includes: forming a light-transmitting medium film 12′ using a chemical vapor deposition (CVD) process, an atomic layer deposition (ALD) process, an evaporation process, etc., and removing portions of the light-transmitting medium film 12′ located on the first metal patterns 110 using a nanoimprint process or an etching process such that a portion of the light-transmitting medium film 12′ located between two adjacent first metal patterns 110 is remained, so that the plurality of light-transmitting medium patterns 120 are formed.

For example, a surface roughness of the light-transmitting medium pattern 120 away from the base 63 is less than 10 nm.

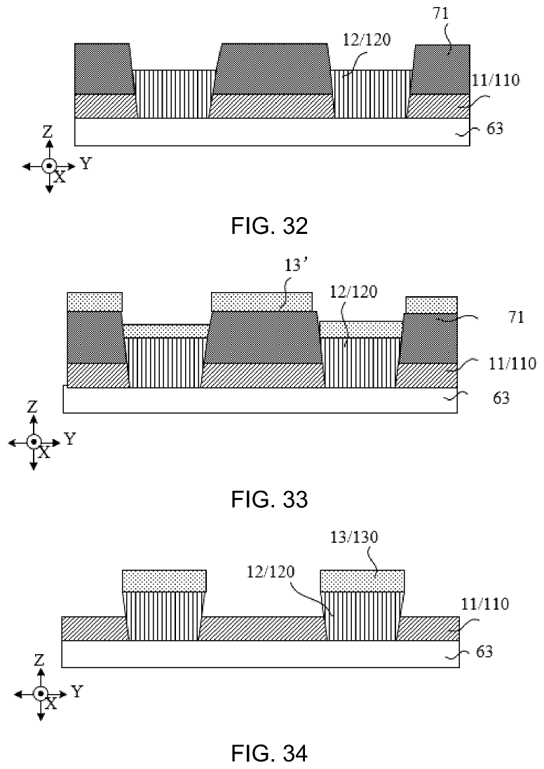

In S440, as shown in FIG. 32, a first sacrificial pattern 71 is formed on each first metal pattern 110; a sum of thicknesses of the first metal pattern 110 and the first sacrificial pattern 71 located on the first metal pattern 110 is greater than the thickness of the light-transmitting medium pattern 120.

For example, the first sacrificial pattern 71 may be made of negative photoresist.

For example, forming the first sacrificial pattern includes: first, coating the first metal patterns 110 and the light-transmitting medium patterns 120 with a negative photoresist material using a spin coating process, and then etching the negative photoresist material located on the light-transmitting medium patterns 120, so that the negative photoresist material located on the first metal patterns 110 are remained, and the plurality of first sacrificial patterns 71 are formed.

For example, the sum of the thicknesses of the first metal pattern 110 and the first sacrificial pattern 71 located on the first metal pattern 110 is greater than the thickness of the light-transmitting medium pattern 120, which may result in a step difference between the first sacrificial pattern 71 and an adjacent light-transmitting medium pattern 120, which in turn facilitates the formation of the second metal patterns 130 in subsequent steps.

In S450, as shown in FIG. 33, a second metal film 13′ is deposited on the plurality of light-transmitting medium patterns 120 and the plurality of first sacrificial patterns 71; a portion of the second metal film 13′ located on each light-transmitting medium pattern 120 and a portion of the second metal film 13′ located on each first sacrificial pattern 71 are disconnected.

For example, the second metal film 13′ may be deposited using electron beam (E-beam) evaporation or thermal evaporation.

Since the sum of the thicknesses of the first metal pattern 110 and the first sacrificial pattern 71 located on the first metal pattern 110 is greater than the thickness of the light-transmitting medium pattern 120, the portion of the second metal film 13′ located on each light-transmitting medium pattern 120 and the portion of the second metal film 13′ located on each first sacrificial pattern 71 cannot be connected, which may ensure the disconnection between the portion of the second metal film 13′ located on each light-transmitting medium pattern 120 and the portion of the second metal film 13′ located on each first sacrificial pattern 71.

In S460, as shown in FIG. 34, each first sacrificial pattern 71 and the portion of the second metal film 13′ located on each first sacrificial pattern 71 are removed so that the portion of the second metal film 13′ located on each light-transmitting medium pattern 120 is remained to obtain a plurality of second metal patterns 130. The plurality of second metal patterns 130 constitute a second metal layer 13. The first metal layer 11, the light-transmitting medium layer 12 and the second metal layer 13 constitute the metal wire grid 10.

For example, as for the structure of the second metal patterns 130, reference may be made to the description of some of the above embodiments of the present disclosure, and details will not be repeated here.

For example, the second metal layer 13 and the first metal layer 11 may be made of the same material.

Since the portion of the second metal film 13′ located on each light-transmitting medium pattern 120 and the portion of the second metal film 13′ located on each first sacrificial pattern 71 are disconnected, during the process of removing each first sacrificial pattern 71 and the portion of the second metal film 13′ located on each first sacrificial pattern 71, the portion of the second metal film 13′ located on each light-transmitting medium pattern 120 will not be involved, which may ensure the dimensional accuracy of the second metal pattern 130, and in turn ensure that the metal wire grid 10 has high light transmittance and high degree of polarization.

For example, each first sacrificial pattern 71 and the portion of the second metal film 13′ located on each first sacrificial pattern 71 may be removed using a lift-off process. Therefore, it may be possible to improve the dimensional accuracy of the second metal pattern 130 in the metal wire grid 10 and improve the fabrication efficiency of the metal wire grid 10.

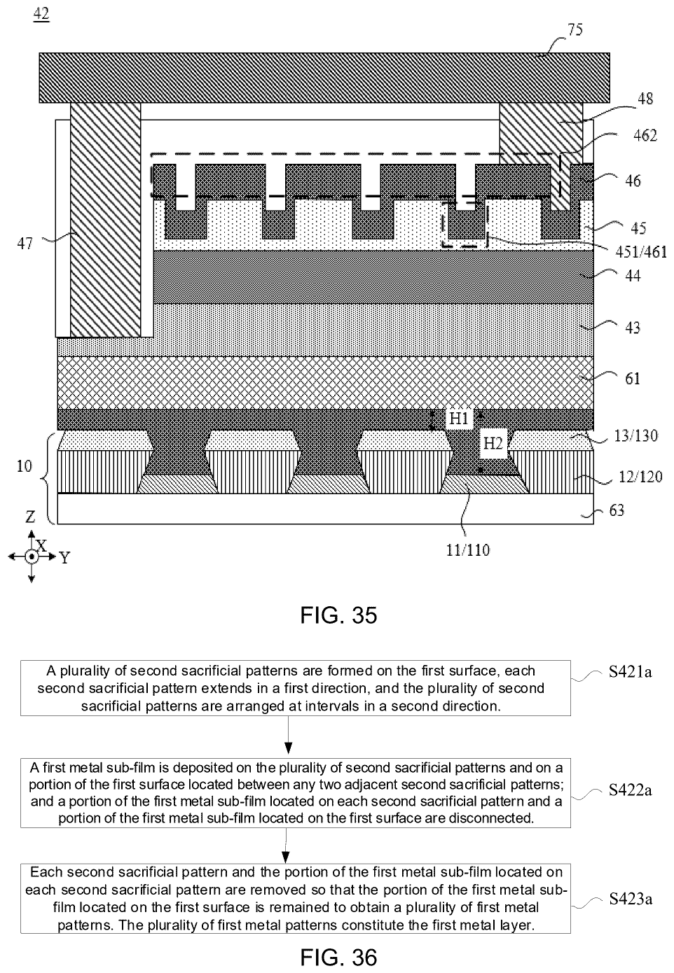

In S470, as shown in FIG. 35, the second metal layer 13 of the metal wire grid 10 is bonded to a surface of the epitaxial structure 04 of the light-emitting device 42 away from the phase deflection layer 46.

For example, before bonding the metal wire grid 10 to the epitaxial structure 04, the epitaxial structure 04 may be turned upside down, or the metal wire grid 10 may be turned upside down.

For example, the metal wire grid 10 and the epitaxial structure 04 may be bonded together using an adhesive material.

For example, the adhesive material may be a light-transmitting material, and a refractive index of the adhesive material is approximately 1.5. Therefore, the absorption of light by the adhesive material may be reduced, the light loss of the light-emitting device 42 is reduced, and the light extraction efficiency of the light-emitting device 42 and the backlight module 40 is improved.

For example, in the light-emitting device 42, a distance H1 between the second metal pattern 130 of the metal wire grid 10 and the connection layer 61 may be 80 nm, and a distance H2 between the first metal pattern 110 and the connection layer 61 may be in a range of 180 nm to 480 nm. For example, the distance H2 between the first metal pattern 110 and the connection layer 61 may be 180 nm, 330 nm or 480 nm. Therefore, the metal wire grid 10 may cooperate with the epitaxial structure 04 so that the metal wire grid 10 has high light transmittance and high degree of polarization.

In some examples, after the second metal layer 13 of the metal wire grid 10 is bonded to the surface of the epitaxial structure 04 of the light-emitting device 42 away from the phase deflection layer 46, the base 63 may be removed, or the thickness of the base 63 may be reduced to 100 nm. Therefore, it may be possible to reduce or even prevent the light emitted by the light-emitting layer 44 from being blocked and absorbed by the base 63, reduce the light loss of the light-emitting device 42, and increase the amount of light emitted by the light-emitting device 42.

In some embodiments of the present disclosure, the metal wire grid 10 is formed by using the method introduced in S410 to S470, and the first metal layer 11 and the second metal layer 13 are formed separately, which may avoid the connection between the first metal pattern 110 and the second metal pattern 130, improves the light transmittance of the metal wire grid 10, and improve the light extraction efficiency of the light-emitting device 42.

It will be understood that the method of forming the first metal layer 11 on the first surface 63A varies, which may be set according to actual needs.

In some embodiments, as shown in FIG. 36, S420 in which the first metal layer 11 is formed on the first surface 63A includes S421a to S423a.

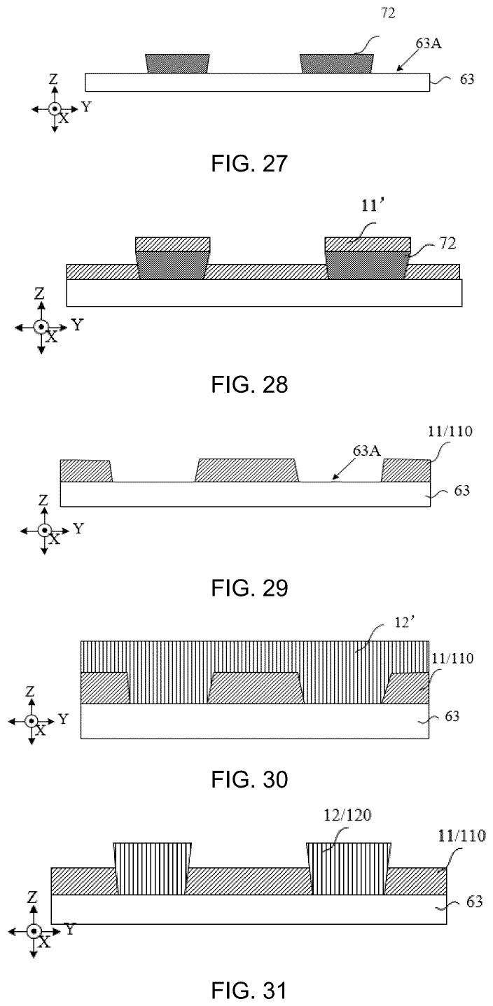

In S421a, as shown in FIG. 27, a plurality of second sacrificial patterns 72 are formed on the first surface 63A, each second sacrificial pattern 72 extends in the first direction X, and the plurality of second sacrificial patterns 72 are arranged at intervals in the second direction Y.

For example, a second sacrificial layer is formed on the first surface 63A using a spin coating process, and the second sacrificial layer is exposed and developed to obtain the plurality of second sacrificial patterns 72.

For example, the second sacrificial patterns 72 may be made of photoresist.

For example, in the sectional view shown in FIG. 27, a section of the second sacrificial pattern 72 may be in a shape of an inverted trapezoid.

In S422a, as shown in FIG. 28, a first metal sub-film 11′ is deposited on the plurality of second sacrificial patterns 72 and on a portion of the first surface 63A located between any two adjacent second sacrificial patterns 72; and a portion of the first metal sub-film 11′ located on each second sacrificial pattern 72 and a portion of the first metal sub-film 11′ located on the first surface 63A are disconnected.

Since there is a step difference between the second sacrificial pattern 72 and the first surface 63A of the base 63, the portion of the first metal sub-film 11′ located on each second sacrificial pattern 72 and the portion of the first metal sub-film 11′ located on the first surface 63A are not connected, which may facilitate the formation of the first metal patterns 110.

In S423a, as shown in FIG. 29, each second sacrificial pattern 72 and the portion of the first metal sub-film 11′ located on each second sacrificial pattern 72 are removed so that the portion of the first metal sub-film 11′ located on the first surface 63A is remained to obtain a plurality of first metal patterns 110. The plurality of first metal patterns 110 constitute the first metal layer 11.

Since the portion of the first metal sub-film 11′ located on each second sacrificial pattern 72 and the portion of the first metal sub-film 11′ located on the first surface 63A are disconnected, during the process of removing each second sacrificial pattern 72 and the portion of the first metal sub-film 11′ located on each second sacrificial pattern 72, the portion of the first metal sub-film 11′ located on the first surface 63A will not be involved, which may ensure the dimensional accuracy of the first metal pattern 110, and in turn ensure that the metal wire grid 10 has high light transmittance and high degree of polarization.

For example, each second sacrificial pattern 72 and the portion of the first metal sub-film 11′ located on each second sacrificial pattern 72 may be removed using a lift-off process. Therefore, it may be possible to improve the dimensional accuracy of each first metal pattern 110 in the metal wire grid 10 and improve the fabrication efficiency of the metal wire grid 10.

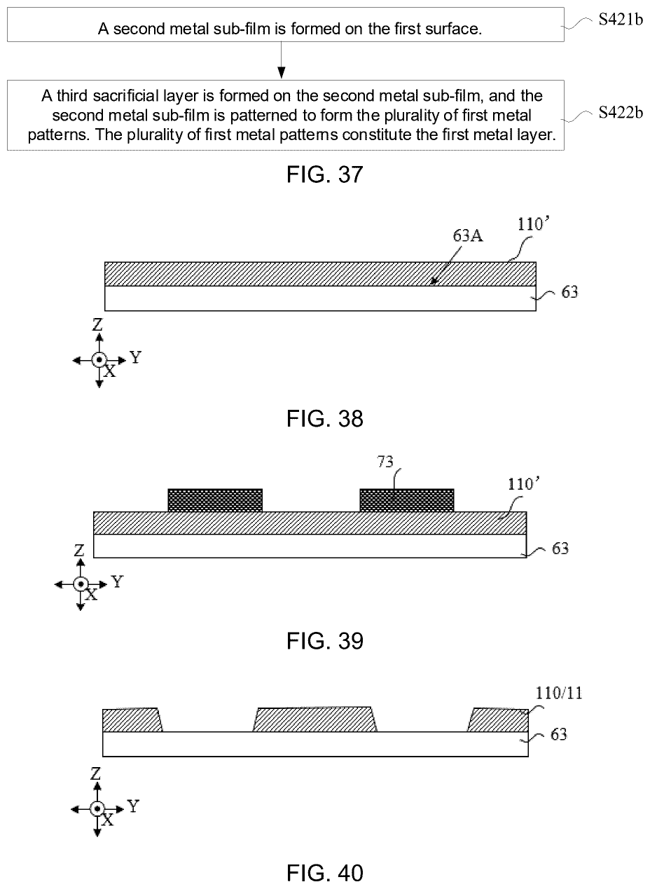

In some other embodiments, as shown in FIG. 37, S420 in which the first metal layer is formed on the first surface includes S421b to S422b.

In S421b, as shown in FIG. 38, a second metal sub-film 110′ is formed on the first surface 63A.

For example, the second metal sub-film 110′ has a flat plate-shaped structure, and the second metal sub-film 110′ covers the first surface 63A.

For example, the second metal sub-film 110′ may be formed by depositing a metal material through an electron beam evaporation or thermal evaporation or sputtering process.

In S422b, as shown in FIGS. 39 and 40, a third sacrificial layer 73 is formed on the second metal sub-film 110′, and the second metal sub-film 110′ is patterned to form the plurality of first metal patterns 110. The plurality of first metal patterns 110 constitute the first metal layer 11.

For example, the third sacrificial layer 73 may be made of photoresist. For example, the second metal sub-film 110′ is coated with a whole layer of photoresist material, and the photoresist material is exposed and developed to form a plurality of third sacrificial patterns, and the plurality of third sacrificial patterns constitute the third sacrificial layer 73.

Patterning the second metal sub-film 110′ may include etching the second metal sub-film 110′ using the third sacrificial layer 73 as a mask to form the plurality of first metal patterns 110.

Since the first metal layer 11 is formed using the above-mentioned method, the fabrication efficiency of the metal wire grid 10 may be improved.

As for the method of integrating the metal wire grid 10 on the epitaxial structure 04, reference may be made to the method of forming the first metal layer 11, the light-transmitting medium layer 12 and the second metal layer 13 of the metal wire grid 10 in some of the above embodiments. For example, the connection layer 61 may be used as the base 63 in S410; the first metal layer is formed on the connection layer 61; the light-transmitting medium layer is formed on the connection layer 61; the first sacrificial pattern is formed on each first metal pattern; the second metal film is deposited on the plurality of light-transmitting medium patterns and the plurality of first sacrificial patterns; each first sacrificial pattern and the portion of the second metal film located on each first sacrificial pattern are removed, so that the portion of the second metal film located on each light-transmitting medium pattern is remained to obtain the plurality of second metal patterns, and the plurality of second metal patterns constitute the second metal layer. The first metal layer, the light-transmitting medium layer and the second metal layer constitute the metal wire grid. The first metal layer is closer to the connection layer 61 than the second metal layer.

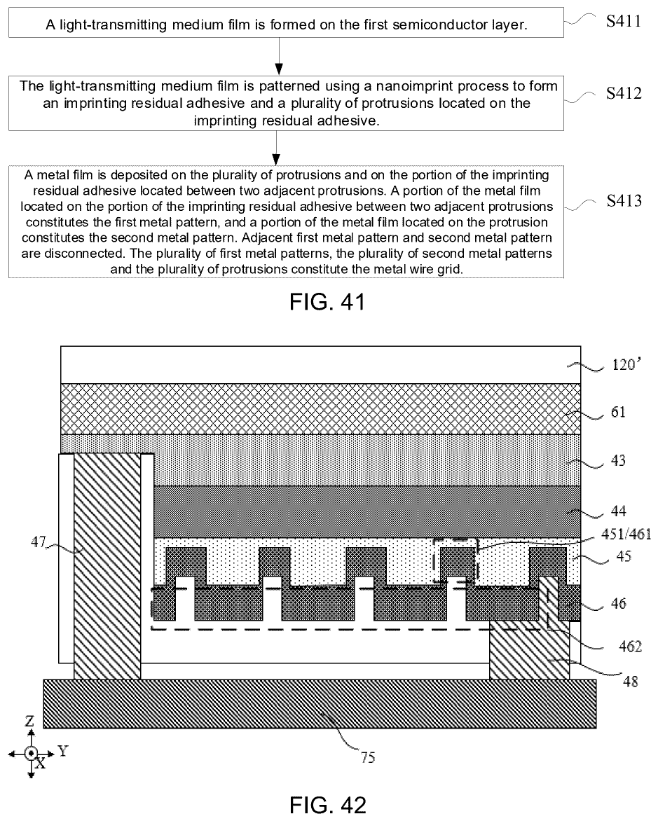

Alternatively, the method of integrating the metal wire grid 10 on the epitaxial structure 04 may be different from the method of forming the first metal layer 11, the light-transmitting medium layer 12 and the second metal layer 13 of the metal wire grid 10 in some of the above embodiments. As shown in FIG. 41, the method of integrating the metal wire grid 10 on the epitaxial structure 04 may include S411 to S413.

In S411, as shown in FIG. 42, a light-transmitting medium film 120′ is formed on the first semiconductor layer 43.

For example, the epitaxial structure 04 may be turned upside down first, and then the light-transmitting medium film 120′ is formed on the first semiconductor layer 43.

For example, the light-transmitting medium film 120′ may be made of polymethyl methacrylate (PMMA).

For example, the light-transmitting medium film 120′ may be formed by using a spin coating process.

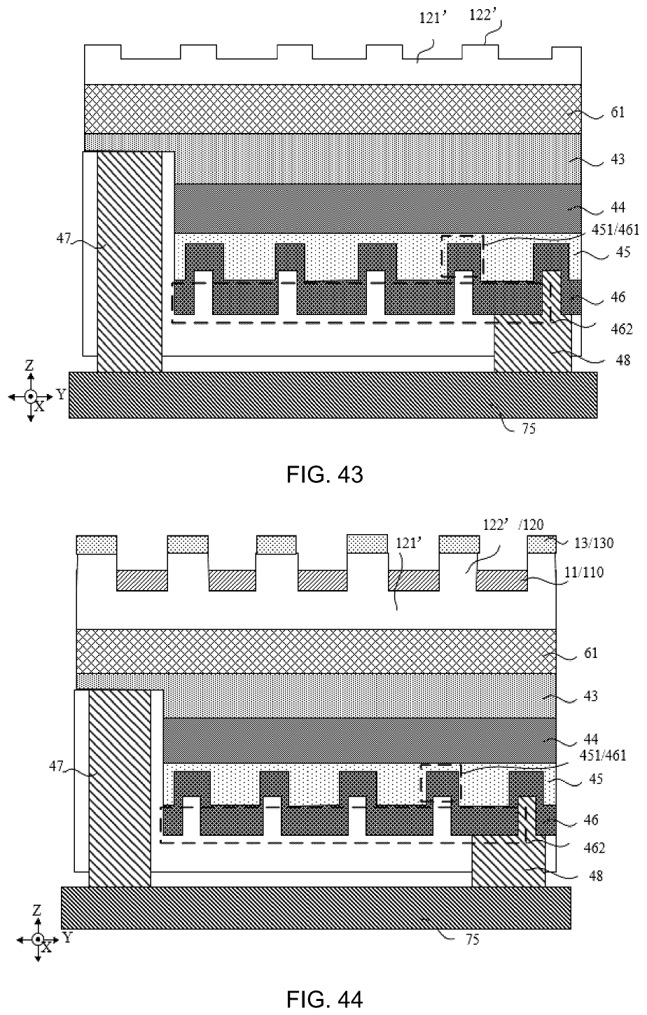

In S412, as shown in FIG. 43, the light-transmitting medium film 120′ is patterned using a nanoimprint process to form an imprinting residual adhesive 121′ and a plurality of protrusions 122′ located on the imprinting residual adhesive.

For example, the light-transmitting medium film 120′ may be imprinted using a mask. The mask has a plurality of grooves, and portions of the light-transmitting medium film are completely filled into the grooves of the mask to form the plurality of protrusions 122′, and the plurality of protrusions 122′ correspond to the light-transmitting medium patterns 120 to be formed. A remaining portion of the light-transmitting medium film 120′ are not pressed into the grooves of the mask to become the imprinting residual adhesive. The imprinting residual adhesive 121′ and the plurality of protrusions 122′ constitute a one-piece structure.

In some examples, the plurality of protrusions 122′ may constitute the plurality of light-transmitting medium patterns 120.

In some other examples, after the above S412, a portion of the imprinting residual adhesive 121′ located between two adjacent protrusions 122′ is etched, so as to form the plurality of light-transmitting medium patterns 120. The plurality of light-transmitting medium patterns 120 constitute the light-transmitting medium layer 12.

For example, in the process of etching the portion of the imprinting residual adhesive 121′ located between two adjacent protrusions 122′, the thicknesses of the plurality of protrusions 122′ may also be reduced to a certain extent. The protrusions whose thicknesses have been reduced constitute the light-transmitting medium pattern 120.

In S413, as shown in FIG. 44, a metal film is deposited on the plurality of protrusions 122′ and on the portion of the imprinting residual adhesive 121′ located between two adjacent protrusions 122′. A portion of the metal film located on the portion of the imprinting residual adhesive between two adjacent protrusions 122 constitutes the first metal pattern 110, and a portion of the metal film located on the protrusion 122′ constitutes the second metal pattern 130. Adjacent first metal pattern 110 and second metal pattern 130 are disconnected. The plurality of first metal patterns 110, the plurality of second metal patterns 130 and the plurality of protrusion 122′ constitute the metal wire grid 10.

In some embodiments, the light-emitting device 42 is of a flip-chip structure, and orthographic projections of the second semiconductor layer 45 and the light-emitting layer 44 on the plane where the metal wire grid 10 is located are located within the orthographic projection of the first semiconductor layer 43 on the plane where the metal wire grid 10 is located. Before forming the metal wire grid 10 on the side of the epitaxial structure 04 away from the phase deflection layer 46, the method further includes S390.

In S390, as shown in FIG. 44, a first electrode 47 and a second electrode 48 are formed. The first electrode 47 is located on the side of the first semiconductor layer 43 away from the metal wire grid 10, and is electrically connected to a portion of the first semiconductor layer 43 extending beyond the light-emitting layer 44 and the second semiconductor layer 45. The second electrode 48 is located on a side of the phase deflection layer 46 away from the metal wire grid 10, and is electrically connected to the second semiconductor layer 45 through the phase deflection layer 46.

For example, the first electrode 47 and the second electrode 48 are arranged in a staggered manner. Thereby, the structural stability of the light-emitting device 42 may be improved.

As for the structural features of the first electrode 47 and the second electrode layer 48, reference may be made to the description of some of the above embodiments, and details will not be repeated here.

For example, the method of forming the first electrode 47 and the second electrode 48 varies, which may be selected according to actual needs.

For example, for the light-emitting device 42 of the flip-chip structure, S390 in which the first electrode 47 and the second electrode 48 are formed further includes S391 to S393.

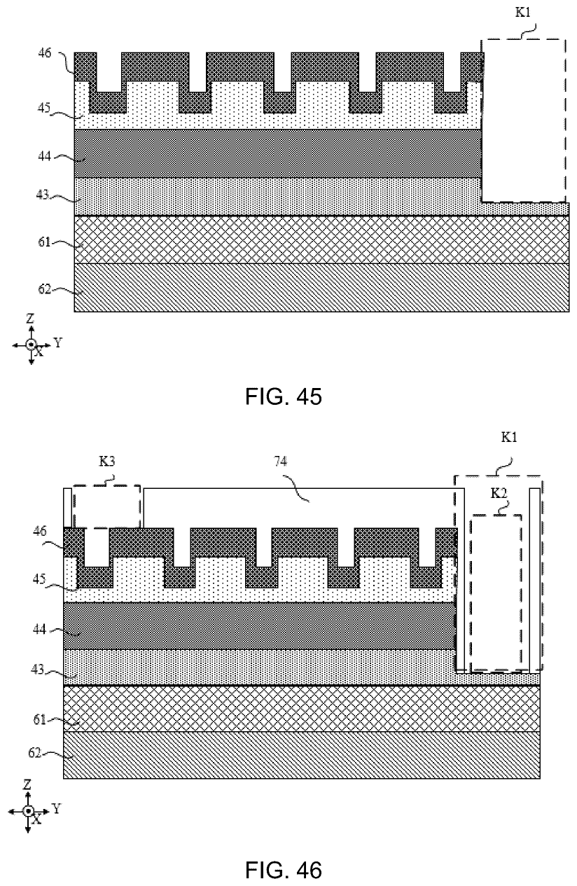

In S391, as shown in FIG. 45, the phase deflection layer 46, the second semiconductor layer 45, and the light-emitting layer 44 of the light-emitting device 42 are etched to form a first sub-hole K1, and the first sub-hole K1 exposes a part of the first semiconductor 43.

For example, the phase deflection layer 46 may be etched using a wet etching process, and the second semiconductor layer 45 may be etched using a dry etching process.

For example, a depth of the first sub-hole K1 may be 1500 nm, and the etching depth uniformity is ±500 nm.

In S392, as shown in FIG. 46, a passivation layer 74 is formed on the phase deflection layer 46. A first via hole K2 is formed in a region of the light-emitting device 42 corresponding to the first sub-hole K1. The first via hole K2 exposes a part of the first semiconductor layer 43, the first sub-hole K1 and the first via hole K2 are concentric, and a diameter of the first via hole K2 is smaller than a diameter of the first sub-hole K1. A second via hole K3 penetrating through the passivation layer 74 is formed in the light-emitting device 42, and the second via hole K3 exposes a part of the second semiconductor layer 45 or a part of the phase deflection layer 46.

For example, the passivation layer 74 may be formed by using a CVD process.

For example, the passivation layer 74 may be made of an insulating material, such as silicon nitride or silicon oxide.

For example, a thickness of the passivation layer 74 may be approximately 250 nm.

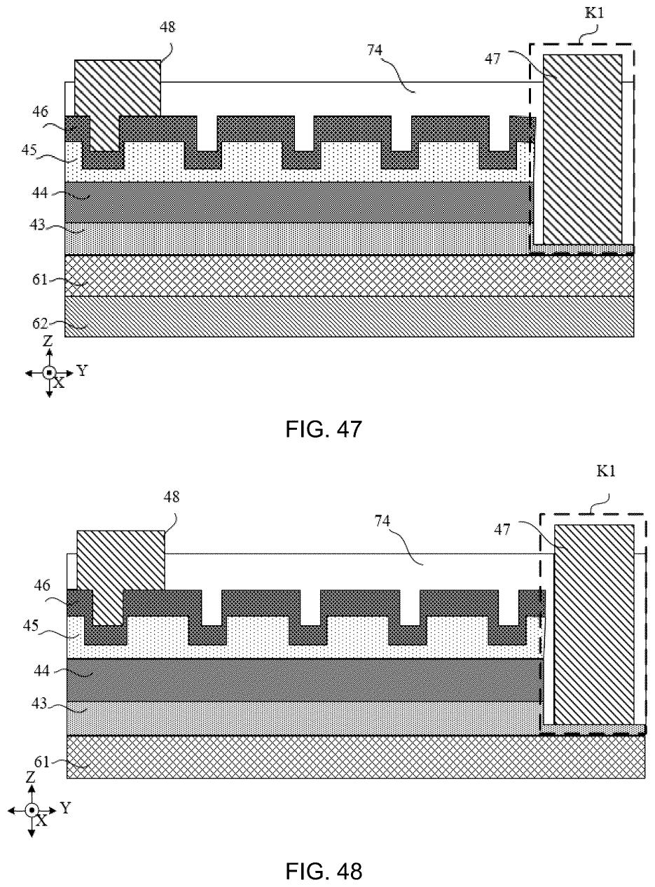

In S393, as shown in FIG. 47, the first electrode 47 is formed in the first via hole K2, and the second electrode 48 is formed in the second via hole K3.

For example, a portion of the passivation layer 74 exists between the first electrode 47 and the first sub-hole K1. The portion of the passivation layer 74 is used to isolate the first electrode 47 from the second semiconductor layer 45 and the phase deflection layer 46.

For example, each of the first electrode 47 and the second electrode 48 may be made of a metal material. The first electrode 47 may be made of titanium, aluminum, nickel, gold, etc., and the second electrode 48 may be made of chromium, platinum, gold, etc.

For example, when the first electrode 47 is made of titanium, the thickness of the first electrode 47 is 30 nm. When the first electrode 47 is made of aluminum, the thickness of the first electrode 47 is 175 nm. When the first electrode 47 is made of nickel, the thickness of the first electrode 47 is 35 nm. When the first electrode 47 is made of gold, the thickness of the first electrode 47 is 1000 nm. When the second electrode 48 is made of chromium, the thickness of the second electrode 48 is 20 nm. When the second electrode 48 is made of platinum, the thickness of the second electrode 48 is 20 nm. When the second electrode 48 is made of gold, the thickness of the second electrode 48 is 1000 nm.

For example, the above metal material may be evaporated using an electron beam evaporation process, and then is annealed at 250° C. for 10 minutes, so that the first electrode 47 and the second electrode 48 are formed.

Since the first electrode 47 and the second electrode 48 are formed by using the above-mentioned method, it may be possible to ensure the electrical connection between the first electrode 47 and the first semiconductor layer 43 and the electrical connection between the second electrode 48 and the second semiconductor layer 45.

In order to avoid damage or contamination of the first electrode 47 and the second electrode 48, as shown in FIG. 35, a temporary carrier 75 is used to bond the first electrode 47 and the second electrode 48.

For example, as shown in FIG. 48, after the first electrode 47 and the second electrode 48 are formed, the first base 62 may be removed.

For example, the first base 62 is a sapphire base, and the first base 62 may be removed using laser. In the case where the first base 62 is a silicon base, the first base 62 may be immersed in hydrofluoric acid, and the first base 62 is removed using hydrofluoric acid.

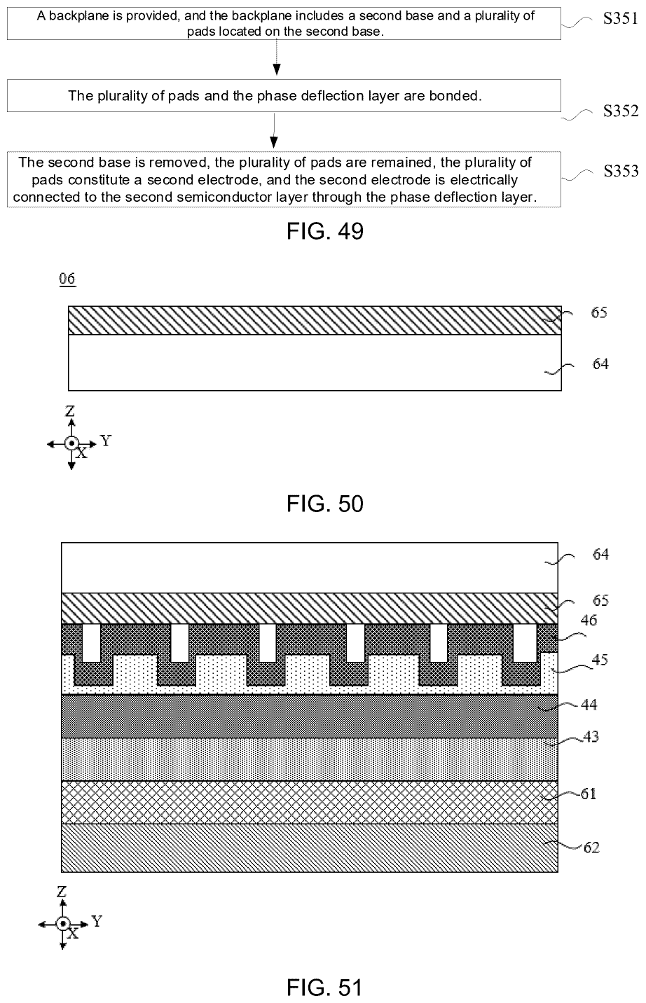

In some other embodiments, the light-emitting device 42 is of a vertical structure, the orthographic projections of the second semiconductor layer 45, the light-emitting layer 44 and the first semiconductor layer 43 on the plane where the metal wire grid 10 is located coincide or substantially coincide with each other. As shown in FIG. 49, before forming the metal wire grid 10 on the side of the epitaxial structure 04 away from the phase deflection layer 46, the method further includes S351 to S353.

In S351, as shown in FIG. 50, a backplane 06 is provided. The backplane includes a second base 64 and a plurality of pads 65 located on the second base 64.

For example, the second base 64 may be a silicon base.

For example, the plurality of pads 65 may be made of tin (Sn) or the like.

For example, the plurality of pads 65 may be formed by evaporating tin material on the second base 64.

In S352, as shown in FIG. 51, the plurality of pads 65 and the phase deflection layer 46 are bonded.

For example, the plurality of pads 65 are bonded to the second sub-portion 462 of the phase deflection layer 46.

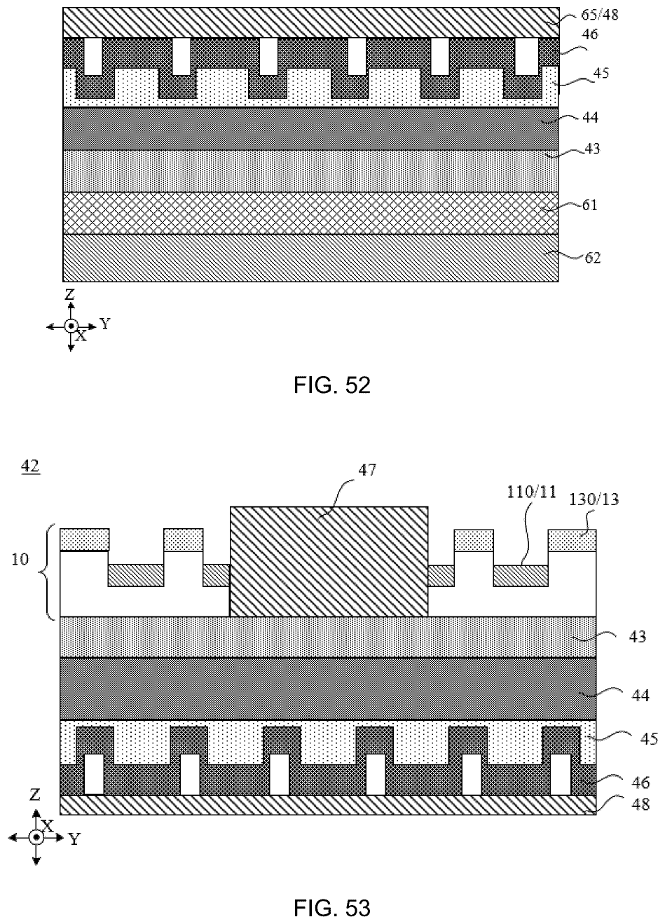

In S353, as shown in FIG. 52, the second base 64 is removed so that the plurality of pads 65 are remained. The plurality of pads 65 constitute the second electrode 48. The second electrode 48 is electrically connected to the second semiconductor layer 45 through the phase deflection layer 46.

For example, the second base 64 may be removed using a hydrofluoric acid immersion method.

In some examples, after forming the metal wire grid 10 on the side of the epitaxial structure 04 away from the phase deflection layer 46, as shown in FIG. 53, the method further includes:
forming the first electrode 47, the first electrode 47 being located on the side of the first semiconductor layer 43 close to the metal wire grid 10 and being electrically connected to the first semiconductor layer 43 by penetrating through the metal wire grid 10.

For example, the method of forming the first electrode 47 may include: etching a first portion of the metal wire grid 10 to form a third via hole, the third via hole exposing a part of the first semiconductor layer 43, and forming the first electrode 47 in the third via hole.

For example, the first electrode 47 is electrically connected to the first semiconductor layer 43.

For example, the first electrode 47 may be made of a metal material. The first electrode 47 may be made of titanium, aluminum, nickel, gold, etc.

For example, when the first electrode 47 is made of titanium, the thickness of the first electrode 47 is 30 nm. When the first electrode 47 is made of aluminum, the thickness of the first electrode 47 is 175 nm. When the first electrode 47 is made of nickel, the thickness of the first electrode 47 is 35 nm. When the first electrode 47 is made of gold, the thickness of the first electrode 47 is 1000 nm.

Since the first electrode 47 and the second electrode 48 are formed by using the above-mentioned method, it may be possible to simplify the manufacturing process of the light-emitting device 42 and reduce the manufacturing difficulty of the light-emitting device.

It will be understood that, as for the method for manufacturing the light-emitting device 42 of a normal structure, reference may also be made to the description of some of the above embodiments, and details will not be repeated here.

The foregoing descriptions are merely specific implementation manners of the present disclosure, but the protection scope of the present disclosure is not limited thereto. Any changes or replacements that a person skilled in the art could conceive of within the technical scope of the present disclosure shall be included in the protection scope of the present disclosure. Therefore, the protection scope of the present disclosure shall be subject to the protection scope of the claims.

1. A light-emitting device, comprising:
a metal wire grid;
a first semiconductor layer located on a side of the metal wire grid;
a light-emitting layer located on a side of the first semiconductor layer away from the metal wire grid;
a second semiconductor layer located on a side of the light-emitting layer away from the metal wire grid, a surface of the second semiconductor layer away from the first semiconductor layer being provided with a plurality of grooves; and
a phase deflection layer covering the second semiconductor layer, and portions of the phase deflection layer being located in the plurality of grooves.

2. The light-emitting device according to claim 1, wherein the metal wire grid includes:
a first metal layer including a plurality of first metal patterns, wherein each first metal pattern extends in a first direction, and the plurality of first metal patterns are arranged at intervals in a second direction, the first direction and the second direction intersecting;
a light-transmitting medium layer including a plurality of light-transmitting medium patterns, wherein each light-transmitting medium pattern extends in the first direction, and the plurality of light-transmitting medium patterns are arranged at intervals in the second direction; the light-transmitting medium pattern is located between two adjacent first metal patterns; a thickness of the light-transmitting medium pattern is greater than a thickness of the first metal pattern; and
a second metal layer including a plurality of second metal patterns, wherein each second metal pattern extends in the first direction, and the plurality of second metal patterns are arranged at intervals in the second direction; a second metal pattern is located on a surface of a light-transmitting medium pattern close to the first semiconductor layer.

3. The light-emitting device according to claim 2, wherein in a direction perpendicular to a plane where the metal wire grid is located and in the second direction, a shape of a section of the first metal pattern includes an upright trapezoid; and/or
in the direction perpendicular to the plane where the metal wire grid is located and in the second direction, a shape of a section of the second metal pattern includes an upright trapezoid.

4. The light-emitting device according to claim 2,
wherein in a direction perpendicular to a plane where the metal wire grid is located and in the second direction, a shape of a section of the light-transmitting medium pattern includes an inverted trapezoid.

5. The light-emitting device according to claim 2, wherein a size of the first metal pattern in the second direction is in a range of 50 nm to 70 nm; and/or
a size of the second metal pattern in the second direction is in a range of 50 nm to 70 nm.

6. The light-emitting device according to claim 2, wherein a distance between any two adjacent first metal patterns in the second direction is substantially equal, and a distance between any two adjacent second metal patterns in the second direction is substantially equal; and/or
a size of each first metal pattern in the second direction is substantially equal, and a size of each second metal pattern in the second direction is substantially equal.

7. The light-emitting device according to claim 2, wherein the thickness of the first metal pattern is in a range of 50 nm to 60 nm; and/or a thickness of the second metal pattern is in a range of 50 nm to 60 nm.

8. The light-emitting device according to claim 2, wherein a thickness of the second metal pattern is substantially equal to the thickness of the first metal pattern.

9. The light-emitting device according to claim 2, wherein a refractive index of the light-transmitting medium pattern is in a range of 1.4 to 1.5.

10. The light-emitting device according to claim 2, wherein a ratio of the thickness of the light-transmitting medium pattern to the thickness of the first metal pattern is in a range of 1.17 to 1.60; and/or, a ratio between the thickness of the light-transmitting medium pattern and a thickness of the second metal pattern is in a range of 1.17 to 1.60.

11. The light-emitting device according to claim 2, wherein orthographic projections of the second semiconductor layer and the light-emitting layer on a plane where the metal wire grid is located are located within an orthographic projection of the first semiconductor layer on the plane where the metal wire grid is located;
the light-emitting device further comprises a first electrode and a second electrode;
the first electrode is located on the side of the first semiconductor layer away from the metal wire grid, and is electrically connected to a portion of the first semiconductor layer extending beyond the light-emitting layer and the second semiconductor layer; the second electrode is located on a side of the phase deflection layer away from the metal wire grid, and is electrically connected to the second semiconductor layer through the phase deflection layer;
wherein the second metal layer is located on a side of the light-transmitting medium layer close to the first semiconductor layer; or
the light-emitting device further comprises a connection layer located between the metal wire grid and the first semiconductor layer, and the second metal layer is located on a side of the light-transmitting medium layer close to the connection layer.

12. The light-emitting device according to claim 2, wherein orthographic projections of the second semiconductor layer, the light-emitting layer and the first semiconductor layer on a plane where the metal wire grid is located substantially coincide with each other;
the light-emitting device further comprises a first electrode and a second electrode;
the first electrode is located on a side of the first semiconductor layer close to the metal wire grid, and is electrically connected to the first semiconductor layer penetrating through the metal wire grid; the second electrode is located on a side of the phase deflection layer away from the metal wire grid, and is electrically connected to the second semiconductor layer through the phase deflection layer;
wherein the second metal layer is located on a side of the light-transmitting medium layer away from the first semiconductor layer.

13. The light-emitting device according to claim 1, wherein the plurality of grooves are arranged in a plurality of rows and a plurality of columns; each row of grooves is arranged in a third direction, and each column of grooves is arranged in a fourth direction; a size of a groove in the fourth direction is greater than a size of the groove in the third direction, the third direction and the fourth direction intersecting and being parallel to a plane where the metal wire grid is located.

14. The light-emitting device according to claim 1, wherein the phase deflection layer includes a plurality of first sub-portions and a second sub-portion connected to the plurality of first sub-portions; a first sub-portion is located in a groove; the second sub-portion is located outside the grooves and located on a side of the second semiconductor layer away from the metal wire grid;
a distance between a surface of the first sub-portion away from the light-emitting layer and the light-emitting layer is less than a distance between a surface of the second sub-portion away from the light-emitting layer and the light-emitting layer.

15. The light-emitting device according to claim 14, wherein a shape of an orthographic projection of the first sub-portion on the light-emitting layer includes a rectangle, an ellipse, or a strip shape.

16. A method for manufacturing a light-emitting device, comprising:
providing an epitaxial structure, the epitaxial structure including a first semiconductor layer, a light-emitting layer, and a second semiconductor layer that are stacked in sequence;
forming a plurality of grooves in a surface of the second semiconductor layer;
forming a phase deflection layer on a side of the second semiconductor layer away from the first semiconductor layer, wherein portions of the phase deflection layer are located in the plurality of grooves; and
forming a metal wire grid on a side of the epitaxial structure away from the phase deflection layer.

17. The method according to claim 16, wherein forming the metal wire grid on the side of the epitaxial structure away from the phase deflection layer includes:
providing a base, the base including a first surface;
forming a first metal layer on the first surface, wherein the first metal layer includes a plurality of first metal patterns, each first metal pattern extends in a first direction, and the plurality of first metal patterns are arranged at intervals in a second direction, the first direction and the second direction intersecting;
forming a light-transmitting medium layer on the first surface, wherein the light-transmitting medium layer includes a plurality of light-transmitting medium patterns, each light-transmitting medium pattern extends in the first direction, and the plurality of light-transmitting medium patterns are arranged at intervals in the second direction; the light-transmitting medium pattern is located between any two adjacent first metal patterns; a thickness of the light-transmitting medium pattern is greater than a thickness of the first metal pattern;
forming a first sacrificial pattern on each first metal pattern, wherein a sum of thicknesses of the first metal pattern and the first sacrificial pattern located on the first metal pattern is greater than the thickness of the light-transmitting medium pattern;
depositing a second metal film on the plurality of light-transmitting medium patterns and a plurality of first sacrificial patterns, wherein in the second metal film, a portion of the second metal film located on each light-transmitting medium pattern and a portion of the second metal film located on each first sacrificial pattern are disconnected;
removing each first sacrificial pattern and the portion of the second metal film located on each first sacrificial pattern so that the portion of the second metal film located on each light-transmitting medium pattern is remained to obtain a plurality of second metal patterns, wherein the plurality of second metal patterns constitute a second metal layer; the first metal layer, the light-transmitting medium layer and the second metal layer constitute the metal wire grid; and
bonding the second metal layer of the metal wire grid to a surface of the epitaxial structure of the light-emitting device away from the phase deflection layer; or
forming the metal wire grid on the side of the epitaxial structure away from the phase deflection layer includes:
forming a light-transmitting medium film on the first semiconductor layer;
patterning the light-transmitting medium film using a nanoimprint process to form an imprinting residual adhesive and a plurality of protrusions located on the imprinting residual adhesive; and
depositing a metal film on the plurality of protrusions and on a portion of the imprinting residual adhesive located between two adjacent protrusions, wherein a portion of the metal film located on the portion of the imprinting residual adhesive between two adjacent protrusions constitutes a first metal pattern, and a portion of the metal film located on a protrusion constitutes a second metal pattern; a first metal pattern and a second metal pattern that are adjacent are disconnected; a plurality of first metal patterns, a plurality of second metal patterns and the plurality of protrusions constitute the metal wire grid.

18-20. (canceled)

21. A backlight module, comprising the light-emitting device according to claim 1.

22. A display apparatus, comprising the backlight module according to claim 21.

23. A display apparatus, comprising the light-emitting device according to claim 1.
